(19) United States
(12) Patent Application Publication
(10) Pub. No.: US 2012/0237873 A1
(43) Pub. Date: Sep. 20, 2012

(54) POSITIVE PHOTOSENSITIVE RESIN COMPOSITION, CURED FILM FORMED FROM THE SAME, AND DEVICE HAVING CURED FILM

(75) Inventors: Takenori Fujiwara, Shiga (JP); Keiichi Uchida, Shiga (JP); Yugo Tanigaki, Shiga (JP); Mitsuhito Suwa, Shiga (JP)

(73) Assignee: TORAY INDUSTRIES INC., CHOU-KU TOKYO (JP)

(21) Appl. No.: 13/513,270

(22) PCT Filed: Dec. 20, 2010
(86) PCT No.: PCT/JP2010/072865

§ 371 Date: Jun. 1, 2012

(30) Foreign Application Priority Data
Dec. 20, 2009 (JP) 2009-290219

(51) Int. Cl. G03F 7/075

(52) U.S. Cl. 430/280.1; 430/281.1

(57) ABSTRACT

Disclosed is a positive photosensitive resin composition which contains a polisiloxane, a naphthoquinone diazide compound, and a solvent. The positive photosensitive resin composition is characterized in that the polysiloxane has: an organosilane-derived structure represented by the general formula (1):

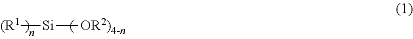

at a content ration of 20-80% inclusive of Si relative to the overall number of moles of Si atoms in the polysiloxane; and an organosilane-derived structure represented by general formula (2):

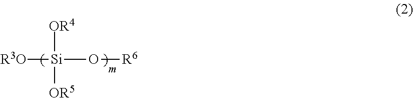

The positive photosensitive resin composition exhibits high heat resistance, high transparency, and enables high sensitivity, high resolution patterning. The positive photosensitive resin composition can be used to form cured films such as planarization films used in TFT substrates, interlayer insulating films, core materials and cladding materials, and can be used in elements having cured films such as display elements, semiconductor elements, solid-state imaging elements, and optical waveguide elements.

### TECHNICAL FIELD

The present invention relates to a photosensitive composition for forming a planarization film for a thin film transistor (TFT) substrate of a liquid crystal display device, an organic EL display device or the like, a protective film or an insulation film for a touch panel sensor element or the like, an interlayer insulation film of a semiconductor device, a planarization film or a microlens array pattern for a solid state image sensing device, or a core or clad material of a light waveguide of a photosemiconductor device or the like; a cured film formed from the photosensitive composition, and a device having the cured film.

### BACKGROUND ART

In recent years, for example, in liquid crystal displays and organic EL displays, a method for enhancing the aperture ratio of a display device is known as a method for achieving further higher precision and higher resolution (refer to Patent Document 1). This is a method which enables to overlap a data line and a pixel electrode each other by providing a transparent planarization film above a TFT substrate as a protective film and increases the aperture ratio compared with a conventional technique.

The materials used as the planarization films for TFT substrates are required to have characteristics such as high heat resistance and high transparency, and to be provided with a hole-pattern of about 50 μm to several micrometers to retain electrical continuity between a TFT substrate electrode and an ITO electrode, and therefore positive photosensitive materials are generally used therefor. As typical positive photosensitive materials, a material of an acrylic resin combined with a quinone diazide compound (refer to Patent Documents 2, 3 and 4) is known.

In recent years, a touch panel is employed in liquid crystal displays and the like, and in order to improve the transparency and the functionality of the touch panel, attempts of heat-treating a transparent electrode member such as ITO at higher temperature or to form a film of the transparent electrode member at higher temperature are made for the purpose of increasing the transparency and the conductivity of the transparent electrode member. With this, heat resistance to high-temperature treatment is required of a protective film or an insulation film of the transparent electrode member. However, since the heat resistance and chemical resistance of an acrylic resin are insufficient, this material has problems that a cured film is colored by high-temperature treatment of a substrate, formation of a film of a transparent electrode at high temperature or treatment with various etching liquids to deteriorate transparency and that the conductivity of an electrode is deteriorated by degassing during the film formation at high temperature.

Also, these acrylic materials are generally low in productivity because of low sensitivity, and therefore a material having higher sensitivity is required. Moreover, with the progress of display, an opening size of a hole pattern or the like is made finer year after year and sometimes formation of a fine pattern of 3 μm or less is required, but the resolution of the above-mentioned acrylic material is not enough.

On the other hand, polysiloxane is known as another material having characteristics such as high heat resistance and high transparency, and a material of the polysiloxane combined with a quinone diazide compound (refer to Patent Documents 5 and 6) for imparting a photosensitive property of a positive type is publicly known. This material has high transparency and enables to attain a cured film with high transparency since its transparency is not deteriorated even in high-temperature treatment of the substrate. However, also in this material, it cannot be said that sensitivity, resolution and chemical resistance are adequate and a positive photosensitive material having higher sensitivity, higher resolution and higher chemical resistance is strongly required. Further, a positive siloxane material (Patent Document 7) using polysiloxane having a quinone diazide structure is publicly known. This material has a problem that a step for incorporating quinone diazide into a polymer structure is added and the process becomes complicated, and transparency of a cured film is low. Further, a positive siloxane material (Patent Document 8), in which polysiloxane having a phenolic hydroxyl group in a polymer is combined with a naphthoquinone diazide compound, is publicly known. This material has a problem that a step for incorporating phenol into a polymer structure is added and the process becomes complicated, and transparency of a cured film is low. This is a material for a two-layer resist and a cured film of the siloxane does not remain on a device.

From the foregoing, there are strong demands for a positive photosensitive material, which satisfies all of higher transparency, higher sensitivity, higher resolution and higher chemical resistance and can be easily produced.

### PRIOR ART DOCUMENTS

### Patent Documents

Patent Document 1: Japanese Unexamined Patent Publication No. 9-152625 (claim 1)
Patent Document 2: Japanese Unexamined Patent Publication No. 2001-281853 (claim 1)
Patent Document 3: Japanese Unexamined Patent Publication No. 5-165214 (claim 1)
Patent Document 4: Japanese Unexamined Patent Publication No. 2002-341521 (claim 1)
Patent Document 5: Japanese Unexamined Patent Publication No. 2006-178436 (claim 1)
Patent Document 6: Japanese Unexamined Patent Publication No. 2009-211033 (claim 1)
Patent Document 7: Japanese Unexamined Patent Publication No. 2007-233125
Patent Document 8: US Patent Application Publication No. 2003/0211407

### SUMMARY OF THE INVENTION

### Problems to be Solved by the Invention

The present invention was made in view of the above-mentioned situations, and it is an object of the present invention to provide a positive photosensitive composition which has characteristics such as high heat resistance and high transparency, can form a pattern with high sensitivity and high resolution, and is excellent in chemical resistance. It is another object of the present invention to provide a cured film formed from the above-mentioned positive photosensitive composition, such as a planarization film for a TFT substrate, an interlayer insulation film, a protective film or an insulation film for a touch panel, a core or clad material and the like; and devices having the cured film such as a display device, a semiconductor device, a solid state image sensing device, and a light waveguide.

### Means for Solving the Problems

In order to solve the above-mentioned problems, the present invention has the following constitution. That is, a positive photosensitive resin composition containing (a) polysiloxane, (b) a naphthoquinone diazide compound, and (c) a solvent, wherein (a) the polysiloxane contains an organosilane-derived structure represented by the general formula (1) in an amount of 20% or more and 80% or less in terms of the ratio of the number of Si atom-moles to the number of Si atom-moles of the whole polysiloxane, and wherein (a) the polysiloxane contains an organosilane-derived structure represented by the general formula (2).

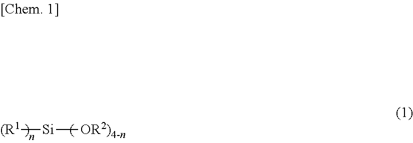

In the formula, R¹ represents an aryl group having 6 to 15 carbon atoms, plural R¹s may be the same or different, R² represents any of hydrogen, an alkyl group having 1 to 6 carbon atoms, an acyl group having 2 to 6 carbon atoms and an aryl group having 6 to 15 carbon atoms and plural R²s may be the same or different, and n represents an integer of 1 to 3.

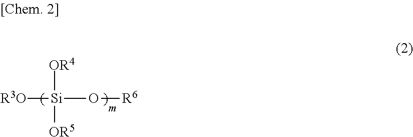

In the formula, R³ to R⁶ independently represent any of hydrogen, an alkyl group having 1 to 6 carbon atoms, an acyl group having 2 to 6 carbon atoms and an aryl group having 6 to 15 carbon atoms and m represents an integer of 1 to 11.

### Effects of the Invention

The photosensitive composition of the present invention has characteristics such as high heat resistance and high transparency and is excellent in chemical resistance. Further, the resulting cured film can be suitably used as a planarization film for a TFT substrate, an interlayer insulation film, or a protective film or an insulation film for a touch panel.

### BRIEF DESCRIPTION OF THE DRAWINGS

FIG. 1 is a schematic sectional view showing an example of a touch panel device.

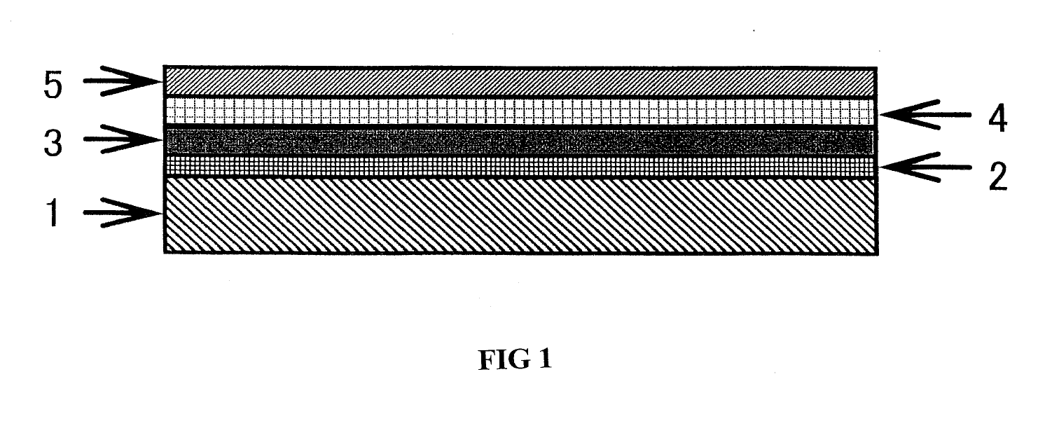

FIG. 2 is a schematic plan view showing an example of a touch panel device.

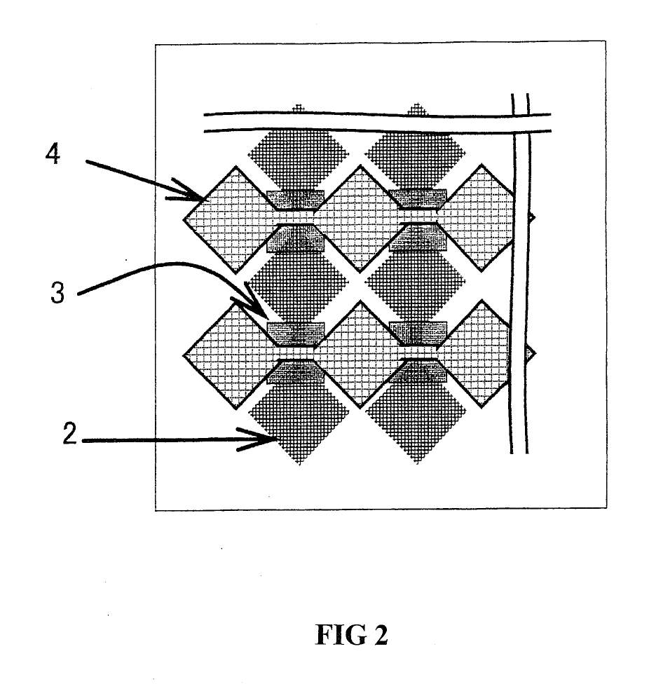

### MODE FOR CARRYING OUT THE INVENTION

The photosensitive composition of the present invention is a positive photosensitive resin composition containing (a) polysiloxane, (b) a naphthoquinone diazide compound, and (c) a solvent, wherein (a) the polysiloxane contains an organosilane-derived structure represented by the general formula (1) in an amount of 20% or more and 80% or less in terms of the ratio of the number of Si atom-moles to the number of Si atom-moles of the whole polysiloxane, and wherein (a) the polysiloxane contains an organosilane-derived structure represented by the general formula (2).

The positive photosensitive composition of the present invention contains (a) polysiloxane synthesized by hydrolyzing and condensing organosilane containing one or more kinds of organosilanes represented by the following general formula (1) and one or more kinds of organosilanes represented by the following general formula (2).

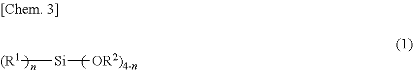

In the organosilane represented by the general formula (1), R¹ represents an aryl group having 6 to 15 carbon atoms and plural R¹s may be the same or different. In addition, these aryl groups all may be an unsubstituted group or may be a substituted group, and can be selected according to characteristics of a composition.

Preferable examples of the aryl group and a substituted group thereof include a phenyl group, a tolyl group, a naphthyl group, an anthracenyl group, a phenanthrenyl group, a fluorenyl group, a fluorenonyl group, a pyrenyl group, an indenyl group, an acenaphthenyl group and the like. These aryl groups are particularly preferred in view of the high transparency of a cured film since they do not have a phenolic hydroxyl group in their skeletons. The aryl group is furthermore preferably a phenyl group, an anthracenyl group, a phenanthrenyl group, a fluorenyl group, a fluorenonyl group, or an acenaphthenyl group, and most preferably a phenyl group.

R² in the general formula (1) represents any of hydrogen, an alkyl group having 1 to 6 carbon atoms, an acyl group having 2 to 6 carbon atoms and an aryl group having 6 to 15 carbon atoms and plural R²s may be the same or different. In addition, these alkyl groups, acyl groups and aryl groups all may be an unsubstituted group or may be a substituted group, and can be selected according to characteristics of a composition. Specific examples of the alkyl group include a methyl group, an ethyl group, an n-propyl group, an isopropyl group, and an n-butyl group. Specific examples of the acyl group include an acetyl group. Specific examples of the aryl group include a phenyl group.

In the general formula (1), n represents an integer of 1 to 3. When n is 1, the organosilane represented by the general formula (1) is a trifunctional silane, and when n is 2, the organosilane is a difunctional silane, and when n is 3, the organosilane is a monofunctional silane.

Specific examples of the organosilane represented by the general formula (1) include trifunctional silanes such as phenyltrimethoxysilane, phenyltriethoxysilane, 1-naphthyltrimethoxysilane, 1-naphthyltriethoxysilane, 1-naphthyltri-n-propoxysilane, 2-naphthyltrimethoxysilane, 1-anthracenyltrimethoxysilne, 9-anthracenyltrimethoxysilne, 9-phenanthrenyltrimethoxysilane, 9-fluorenyltrimethoxysilane, 2-fluorenyltrimethoxysilane, 2-fluorenonyltrimethoxysilane, 1-pyrenyltrimethoxysilane, 2-indenyltrimethoxysilane and 5-acenaphthenyltrimethoxysilane; difunctional silanes such as diphenyldimethoxysilane, diphenyldiethoxysilane, di(1-naphthyl)dimethoxysilane, di(1-naphthyl)diethoxysilane, di(1-naphthyl)di-n-propoxysilane, di(1-naphthyl)di-n-butoxy silane, di(2-naphthyl)dimethoxysilane, 1-naphthylmethyldimethoxysilane, 1-naphthylethyldimethoxysilane, di(1-anthracenyl)dimethoxysilane and di(9-anthracenyl)dimethoxysilane; and monofunctional silanes such as triphenylmethoxysilane and triphenylethoxysilane. These organosilanes may be used singly or may be used in combination of two or more species thereof. Among these organosilanes, a trifunctional silane is preferably used in view of the crack resistance and hardness of a cured film, and phenyltrimethoxysilane and 1-naphthyltrimethoxysilane are preferred.

In (a) the polysiloxane used in the present invention, for the purpose of forming a uniform cured film without causing phase separation by retaining adequate compatibility between the polysiloxane and a naphthoquinone diazide compound described later, the ratio of an organosilane-derived structure represented by the general formula (1) in (a) the polysiloxane is 20% or more and 80% or less in terms of the ratio of the number of Si atom-moles to the number of Si atom-moles of the whole polysiloxane, preferably 25% or more and 70% or less, and moreover preferably 30% or more and 65% or less.

When the content of the organosilane represented by the general formula (1) is more than 80% in terms of the ratio of the number of Si atom-moles, crosslinking at the time of thermal curing does not adequately occur and the chemical resistance of a cured film is deteriorated. Further, when the content of the organosilane is less than 20%, the compatibility between the polysiloxane and the naphthoquinone diazide compound is deteriorated and the transparency of a cured film is deteriorated. When the content of the organosilane represented by the general formula (1) is less than 20% in terms of the ratio of the number of Si atom-moles, phase separation occurs between the polysiloxane and the naphthoquinone diazide compound during application, drying or thermal curing of the composition, and this makes the film cloudy and deteriorates the transmittance of the cured film.

The content of the organosilane-derived structure of the general formula (1) can be determined, for example, by measuring ²⁹Si-NMR of polysiloxane and calculating the ratio of the peak area of Si, with which an aryl group is coupled, to the peak area of Si, with which an aryl group is not coupled, in the general formula (1). Further, in addition to ²⁹Si-NMR, the content can be determined by using ¹H-NMR, ¹³C-NMR, IR, TOF-MS, an elemental analysis method, ash measurement and the like in combination.

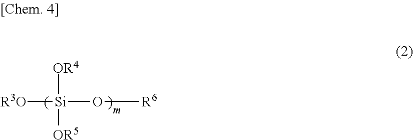

In the organosilane represented by the general formula (2), R³ to R⁶ independently represent any of hydrogen, an alkyl group having 1 to 6 carbon atoms, an acyl group having 2 to 6 carbon atoms and an aryl group having 6 to 15 carbon atoms. These alkyl groups, acyl groups and aryl groups all may be an unsubstituted group or may be a substituted group, and can be selected according to characteristics of a composition. Specific examples of the alkyl group include a methyl group, an ethyl group, an n-propyl group, an isopropyl group, and an n-butyl group. Specific examples of the acyl group include an acetyl group. Specific examples of the aryl group include a phenyl group. In the general formula (2), m represents an integer of 1 to 11. When m is more than 11, it is not preferred since there is a possibility that development residue may be produced. m is preferably an integer of 1 to 8 and more preferably an integer of 3 to 8 in view of the compatibility between chemical resistance and sensitivity.

Specific examples of the organosilane represented by the general formula (2) include tetrafunctional silanes such as tetrarnethoxysilane, tetraethoxysilane, tetrapropoxysilane, tetra-n-butylsilane and tetraphenoxysilane as examples when m=1; and silicate compounds such as Methyl Silicate 51 (m=4, average) (produced by Fuso Chemical Co., Ltd.), M Silicate 51 (m=4, average), Silicate 40 (m=5, average), Silicate 45 (m=7, average) (produced by TAMA CHEMICALS CO., LTD.), Methyl Silicate 51 (m=4, average), Methyl Silicate 53A (m=7, average), Ethyl Silicate 40 (m=5, average), and Ethyl Silicate 48 (m=10, average) (produced by COLCOAT Co., Ltd.) as examples when m is 2 or more, and silicate compounds are preferable from the viewpoint of high sensitivity.

By using the organosilane represented by the general formula (2), a positive photosensitive composition having excellent chemical resistance while maintaining high heat resistance and high transparency can be obtained. In the photosensitive composition of the present invention, (a) the polysiloxane preferably contains the organosilane represented by the general formula (2) in an amount of 5% or more and 80% or less, more preferably 12% or more and 60% or less, and furthermore preferably 25% or more and 60% or less in terms of the ratio of the number of Si atom-moles to the number of Si atom-moles of the whole polysiloxane. Moreover preferably, the upper limit of the ratio is less than 60%. When the ratio is more than 80%, the compatibility between the polysiloxane and the naphthoquinone diazide compound may be deteriorated and the transparency of a cured film may be deteriorated. Further, when the ratio is less than 5%, sometimes the composition cannot exhibit high chemical resistance. The content ratio of the organosilane represented by the general formula (2) can be determined, for example, by measuring ²⁹ Si-NMR of polysiloxane and calculating the ratio of the peak area of Si derived from a tetrafunctional silane in the general formula (2) to the peak area of Si other than Si derived from a tetrafunctional silane in the general formula (2). Further, in addition to ²⁹Si-NMR, the content ratio can be determined by using ¹H-NMR, ¹³C-NMR, IR, TOF-MS, an elemental analysis method, ash measurement and the like in combination.

As an aspect of (a) the polysiloxane, polysiloxane, which is synthesized by reacting organosilane containing one or more kinds of organosilanes represented by the general formula (1) and one or more kinds of organosilanes represented by the general formula (2), and further containing organosilane represented by the general formula (3), may be used.

[Chem. 5]

(R⁷ₗ—Si—OR⁸)₄₋ₗ (3)

In the organosilane represented by the general formula (3), R⁷ represents any of an alkyl group having 1 to 10 carbon atoms and an alkenyl group having 2 to 10 carbon atoms and plural R⁷s may be the same or different. In addition, these alkyl groups and alkenyl groups all may be an unsubstituted group or may be a substituted group, and can be selected according to characteristics of a composition. Specific examples of the alkyl group and a substituted group thereof include a methyl group, an ethyl group, an n-propyl group, an isopropyl group, an n-butyl group, a t-butyl group, an n-hexyl group, an n-decyl group, a trifluoromethyl group, a 3,3,3-trifluoropropyl group, a 3-glycidoxypropyl group, a 2-(3,4-epoxycyclohexyl)ethyl group, a [(3-ethyl-3-oxetanyl)methoxy]propyl group, a 3-aminopropyl group, a 3-mercaptopropyl group, and a 3-isocyanatepropyl group. Specific examples of the alkenyl group and a substituted group thereof include a vinyl group, a 3-acryloxypropyl group and a 3-methacryloxypropyl group.

R⁸ in the general formula (3) represents any of hydrogen, an alkyl group having 1 to 6 carbon atoms, an acyl group having 2 to 6 carbon atoms and an aryl group having 6 to 15 carbon atoms and plural R⁸s may be the same or different. In addition, these alkyl groups, acyl groups and aryl groups all may be an unsubstituted group or may be a substituted group, and can be selected according to characteristics of a composition. Specific examples of the alkyl group include a methyl group, an ethyl group, an n-propyl group, an isopropyl group, and an n-butyl group. Specific examples of the acyl group include an acetyl group. Specific examples of the aryl group include a phenyl group.

In the general formula (3), l represents an integer of 1 to 3. When l is 1, the organosilane represented by the general formula (3) is a trifunctional silane, and when l is 2, the organosilane is a difunctional silane, and when l is 3, the organosilane is a monofunctional silane.

Specific examples of the organosilane represented by the general formula (3) include trifunctional silanes such as methyltrimethoxysilane, methyltriethoxysilane, methyltriisopropoxysilane, methyl tri-n-butoxy silane, ethyltrimethoxysilane, ethyltriethoxysilane, ethyltriisopropoxysilane, ethyl tri-n-butoxy silane, n-propyltrimethoxysilane, n-propyltriethoxysilane, n-butyltrimethoxysilane, n-butyltriethoxysilane, n-hexyltrimethoxysilane, n-hexyltriethoxysilane, decyltrimethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, trifluoromethyltrimethoxysilane, trifluoromethyltriethoxysilane, 3,3,3-trifluoropropyltrimethoxysilane, 3-aminopropyltrimethoxysilane, 3-aminopropyltriethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, [(3-ethyl-3-oxetanyl)methoxy]propyltrimethoxysilane, [(3-ethyl-3-oxetanyl)methoxy]propyltriethoxysilane, 3-mercaptopropyltrimethoxysilane and 3-trimethoxysilylpropylsuccinic acid; difunctional silanes such as dimethyldimethoxysilane, dimethyldiethoxysilane, dimethyldiacetoxysilane, di-n-butyldimethoxysilane, (3-glycidoxypropyl)methyldimethoxysilane and (3-glycidoxypropyl)methyldiethoxysilane; and monofunctional silanes such as trimethylmethoxysilane, tri-n-butylethoxysilane, (3-glycidoxypropyl)dimethylmethoxysilane and (3-glycidoxypropyl)dimethylethoxysilane.

In addition, these organosilanes may be used singly or may be used in combination of two or more species thereof. Among these organosilanes, a trifunctional silane is preferably used in view of the crack resistance and hardness of a cured film, and methyltrimethoxysilane, 3-glycidoxypropyltriethoxysilane, 2-(3,4-epoxycyclohexyl)ethyltrimethoxysilane and 3-methacryloxypropyltriethoxysilane are particularly preferably used.

In the case where the organosilane represented by the general formula (3) is used, the content ratio of the organosilane is not particularly limited, but it is preferably 50% or less in terms of the ratio of the number of Si atom-moles of the organosilane to the number of Si atom-moles of the whole polysiloxane. When the content ratio of the organosilane is more than 50%, the compatibility between the polysiloxane and the naphthoquinone diazide compound is deteriorated and the transparency of a cured film may be deteriorated.

As an aspect of (a) the polysiloxane, polysiloxane, which is synthesized by reacting one or more kinds of organosilanes represented by the general formula (1), one or more kinds of organosilanes represented by the general formula (2) and silica particles, may be used. By reacting the organosilanes with silica particles, resolution of patterns is improved. The reason for this is thought to be that silica particles incorporated into the polysiloxane increase the glass transition temperature of the film and therefore suppress pattern reflow at the time of thermal curing.

The number average particle diameter of the silica particles is preferably 2 to 200 nm, and more preferably 5 to 70 nm. When the number average particle diameter is smaller than 2 nm, the effect of improving the resolution of patterns is not sufficient, and when the number average particle diameter is larger than 200 nm, the resulting cured film scatters light and the transparency of the cured film is deteriorated. Herein, as for the number average particle diameter of the silica particles, in a specific surface area method, the silica particles are dried and fired, specific surface areas of the resulting particles are measured, and then particle diameters are derived from the specific surface areas assuming that the particles are spherical to determine an average particle diameter in terms of a number average value. Equipment used for measuring the average particle diameter is not particularly limited, and for example, ASAP 2020 (manufactured by Microrneritics Instrument Corp.) can be employed.

Specific examples of the silica particles include IPA-ST using isopropanol as a dispersion medium and having a particle diameter of 12 nm, MIBK-ST using methyl isobutyl ketone as a dispersion medium and having a particle diameter of 12 nm, IPA-ST-L using isopropanol as a dispersion medium and having a particle diameter of 45 nm, IPA-ST-ZL using isopropanol as a dispersion medium and having a particle diameter of 100 nm, PGM-ST using propylene glycol monomethyl ether as a dispersion medium and having a particle diameter of 15 nm (these are trade names, produced by Nissan Chemical Industries, Ltd.), OSCAL 101 using gamma-butyrolactone as a dispersion medium and having a particle diameter of 12 nm, OSCAL 105 using gamma-butyrolactone as a dispersion medium and having a particle diameter of 60 nm, OSCAL 106 using diacetone alcohol as a dispersion medium and having a particle diameter of 120 nm, CATALOID-S using water as a dispersion medium and having a particle diameter of 5 to 80 nm (these are trade names, produced by Catalysts & Chemicals Ind. Co., Ltd.), Quartron PL-2L-PGME using propylene glycol monomethyl ether as a dispersion medium and having a particle diameter of 16 nm, Quartron PL-2L-BL using gamma-butyrolactone as a dispersion medium and having a particle diameter of 17 nm, Quartron PL-2L-DAA using diacetone alcohol as a dispersion medium and having a particle diameter of 17 nm, Quartron PL-2L and GP-2L using water as a dispersion medium and having a particle diameter of 18 to 20 nm (these are trade names, produced by FUSO CHEMICAL CO., LTD.), Silica (SiO₂) SG-SO 100 having a particle diameter of 100 nm (trade name, produced by KCM Corp.), and REOLOSIL having a particle diameter of 5 to 50 nm (trade name, produced by Tokuyama Corp.). Further, these silica particles may be used singly or in combination of two or more species thereof.

In the case where the silica particles are used, the mixing ratio of the silica particles to the polysiloxane is not particularly limited, but it is preferably 50% or less in terms of the ratio of the number of Si atom-moles of the silica particles to the number of Si atom-moles of the whole polysiloxane. When this ratio is more than 50%, the compatibility between the polysiloxane and the naphthoquinone diazide compound is deteriorated and the transparency of a cured film is deteriorated.

The weight average molecular weight (Mw) of the polysiloxane used in the present invention is not particularly limited, but it is preferably 1000 to 100000, and more preferably 1500 to 50000 on the polystyrene equivalent basis measured by GPC (gel permeation chromatography). When the Mw is smaller than 1000, the coatability of the composition becomes poor, and when it is larger than 100000, the solubility of the composition in a developer during patterning is deteriorated.

The polysiloxane in the present invention is synthesized by hydrolyzing and partially condensing monomers such as organosilanes represented by the general formulas (1), (2) and (3). A common method can be used for the hydrolysis and partial condensation. For example, a solvent, water, and a catalyst as required are added to a mixture, and the obtained mixture is heated and stirred at 50 to 150° C., preferably 90 to 130° C., for about 0.5 to 100 hours. Further, during stirring, as required, the hydrolysis by-product (alcohols such as methanol) and condensation by-product (water) may also be distilled off.

A solvent for the above-mentioned reaction is not particularly limited, but a solvent similar to (c) a solvent described later is commonly used. An additive amount of the solvent is preferably 10 to 1000 parts by weight with respect to 100 parts by weight of monomers such as organosilane. An additive amount of water to be used for a hydrolysis reaction is preferably 0.5 to 2 moles with respect to 1 mole of a hydrolyzable group.

The catalyst added as required is not particularly limited, but an acid catalyst and a basic catalyst are preferably used. Specific examples of the acid catalysts include hydrochloric acid, nitric acid, sulfuric acid, hydrofluoric acid, phosphoric acid, acetic acid, trifluoroacetic acid, formic acid, polyhydric carboxylic acid or anhydride thereof, and an ion-exchange resin. Specific examples of the basic catalyst include triethylamine, tripropylamine, tributylamine, tripentylamine, trihexylamine, triheptylamine, trioctylamine, diethylamine, triethanolamine, diethanolamine, sodium hydroxide, potassium hydroxide, alkoxy silane having an amino group and an ion-exchange resin. An additive amount of the catalyst is preferably 0.01 to 10 parts by weight with respect to 100 parts by weight of monomers such as organosilane.

In view of the storage stability of the composition, it is preferable that a polysiloxane solution obtained after hydrolysis and partial condensation does not contain the above-mentioned catalyst, and the catalyst can be removed as required. The method for removing the catalyst is not particularly limited, but it is preferred to treat the catalyst by washing with water and/or with an ion-exchange resin in view of ease of operation and removability. Washing with water is a method in which the polysiloxane solution is diluted with an adequate hydrophobic solvent and is washed with water several times and the resulting organic layer is concentrated using an evaporator or the like. Treatment with an ion-exchange resin is a method in which the polysiloxane solution is brought into contact with an adequate ion-exchange resin.

The positive photosensitive composition of the present invention contains (b) a naphthoquinone diazide compound. The photosensitive composition containing the naphthoquinone diazide compound forms a positive type in which an exposed area is removed by a developer. The naphthoquinone diazide compound to be used is not particularly limited, but it is preferably a compound having naphthoquinonediazidesulfonate-bonded to a compound having a phenolic hydroxyl group, and a compound, in which the ortho-position and the para-position of the phenolic hydroxyl group are, respectively independently, occupied by any of a hydrogen atom, a hydroxyl group and a substituent represented by the general formulas (5) to (6), is used as the naphthoquinone diazide compound.

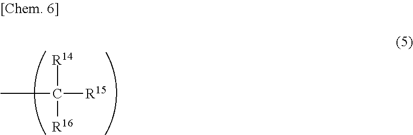

In the formula, R¹⁴, R¹⁵ and R¹⁶ independently represent any of an alkyl group having 1 to 10 carbon atoms, a carboxyl group, a phenyl group and a substituted phenyl group. Further, R¹⁴, R¹⁵ and R¹⁶ may form a ring with one another. The alkyl groups may be an unsubstituted group or may be a substituted group, and can be selected according to characteristics of a composition. Specific examples of the alkyl group include a methyl group, an ethyl group, an n-propyl group, an isopropyl group, an n-butyl group, an isobutyl group, a t-butyl group, an n-hexyl group, a cyclohexyl group, an n-heptyl group, an n-octyl group, a trifluoromethyl group and a 2-carboxyethyl group. Further, examples of a substituent on the phenyl group include a hydroxyl group and a methoxy group. Further, specific examples of the ring in the case where R¹⁴, R¹⁵ and R¹⁶ form a ring with one another include a cyclopentane ring, a cyclohexane ring, an adamantane ring, and a fluorene ring.

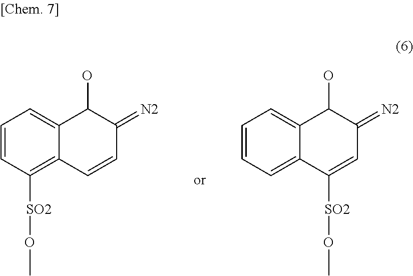

When each group at the ortho position and the para position of the phenolic hydroxyl group is other than the above-mentioned groups, for example, a methyl group, thermal curing causes oxidative decomposition, and a conjugated compound typified by a quinoid structure is formed to color the cured film, thus lowering the transparent and colorless property. These naphthoquinone diazide compounds can be synthesized by a publicly known esterification reaction of the compound having a phenolic hydroxyl group with naphthoquinonediazidesulfonic acid chloride.

Specific examples of the compound having a phenolic hydroxyl group include the following compounds (all of them are produced by Honshu Chemical Industry Co., Ltd.).

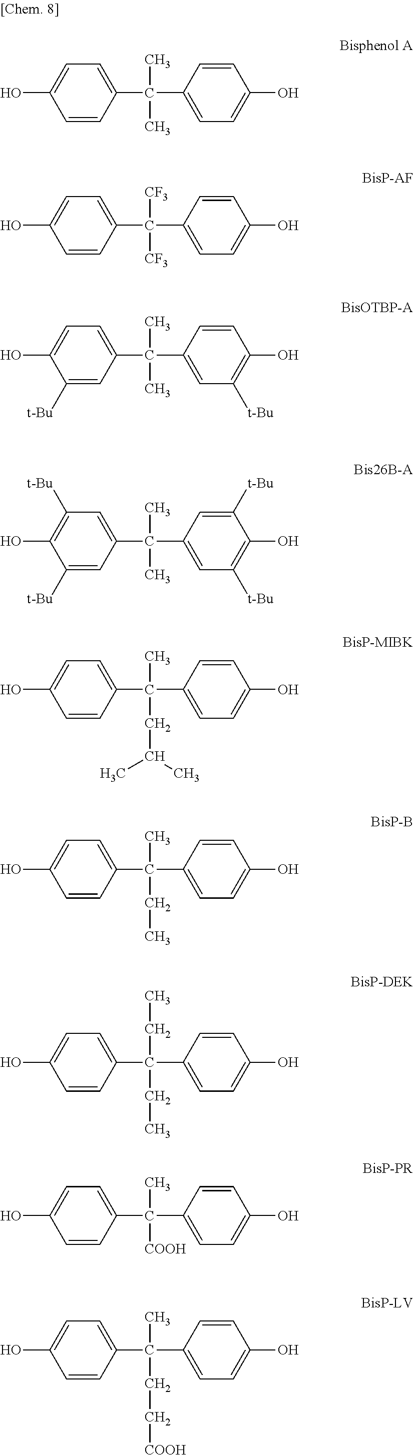

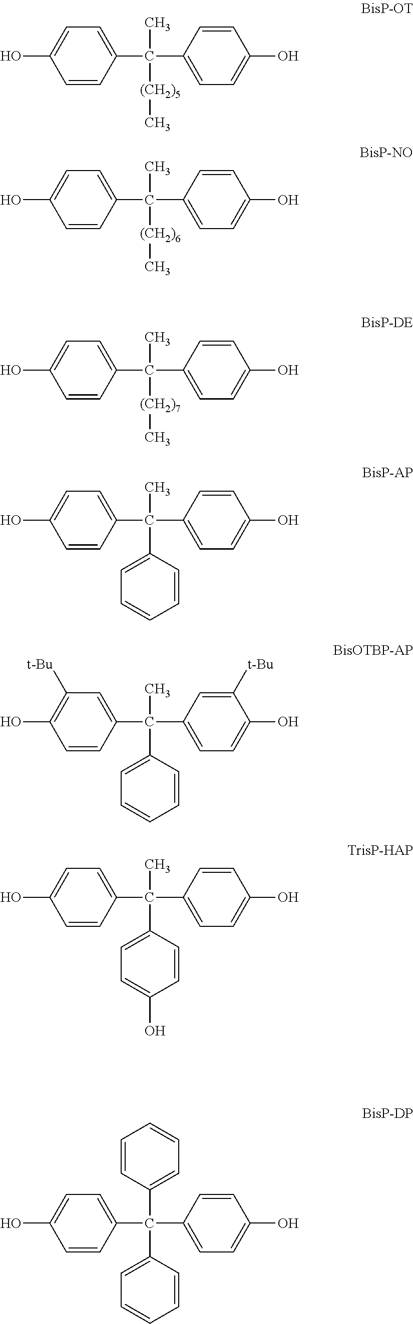

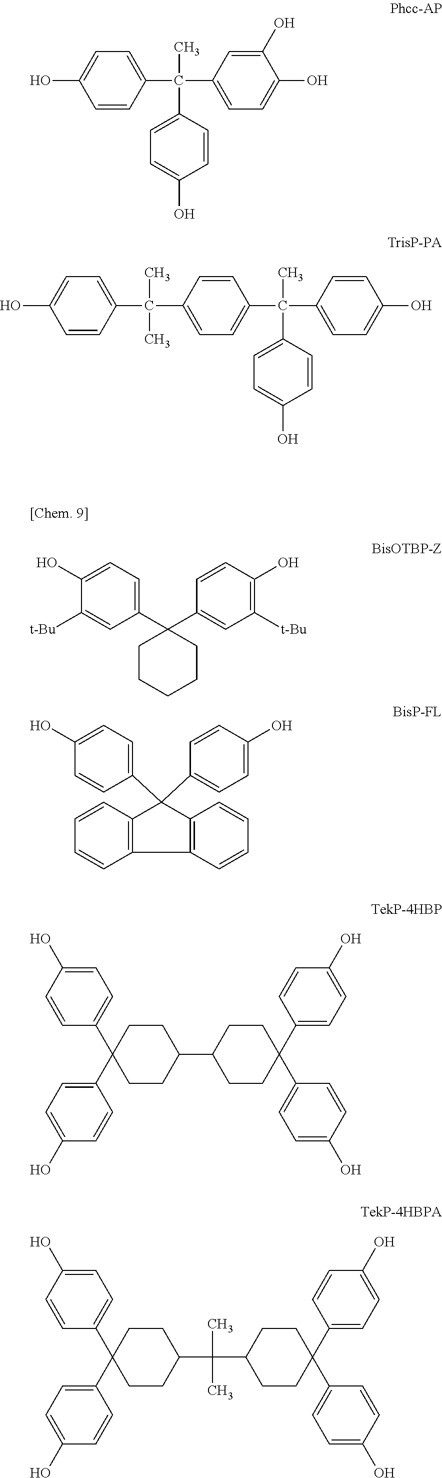

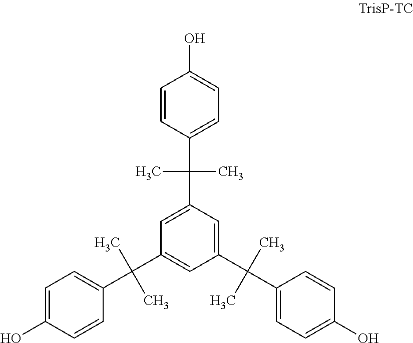

As the naphthoquinonediazidesulfonic acid chloride to be used as a raw material, 4-naphthoquinonediazidesulfonic acid chloride or 5-naphthoquinonediazidesulfonic acid chloride can be employed. A 4-naphthoquinonediazidesulfonic ester compound is suitable for i-beam exposure since it has an absorption band of light in i-beam (wavelength 365 nm) region. Furthermore, a 5-naphthoquinonediazidesulfonic ester compound is suitable for exposure in a wide range of wavelengths since it has an absorption band of light in a wide range of wavelength region. It is preferred to select the 4-naphthoquinonediazidesulfonic ester compound or the 5-naphthoquinonediazidesulfonic ester compound, depending on the wavelength used for exposure. A mixture of the 4-naphthoquinonediazidesulfonic ester compound and the 5-naphthoquinonediazidesulfonic ester compound can also be used.

Examples of the naphthoquinone diazide compound preferably used in the present invention include compounds represented by the following general formula (4).

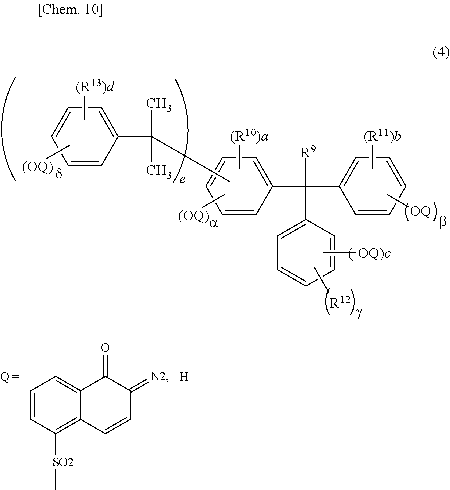

In the formula, R⁹ represents hydrogen or an alkyl group having 1 to 8 carbon atoms. R¹⁰, R¹¹, R¹² and R¹³ represent any of a hydrogen atom, an alkyl group having 1 to 8 carbon atoms, an alkoxyl group, a carboxyl group and an ester group. R¹⁰s, R¹¹s, R¹²s and R¹³s may be the same or different. Q represents either a 5-naphthoquinonediazidesulfonyl group or a hydrogen atom and not all the Qs are a hydrogen atom. a, b, c, d, e, α, β, γ and δ represent an integer of 0 to 4 and satisfy a relationship of α+β+γ+δ≧2. When the naphthoquinone diazide compound represented by the general formula (4) is used, the sensitivity in pattern processing and the resolution are improved.

An additive amount of the naphthoquinone diazide compound is not particularly limited, but it is preferably 2 to 30 parts by weight with respect to 100 parts by weight of a resin (polysiloxane), and more preferably 3 to 15 parts by weight.

When the additive amount of the naphthoquinone diazide compound is less than 1 parts by weight, the photosensitive composition does not exhibit photosensitivity sufficient for a practical use because of too low a dissolution contrast between an exposed area and an unexposed area. The additive amount of the naphthoquinone diazide compound is preferably 5 parts by weight or more in order to attain a more excellent dissolution contrast. On the other hand, when the additive amount of the naphthoquinone diazide compound is more than 30 parts by weight, the transparent and colorless property of a cured film is deteriorated since a coating film is whitened because of deteriorated compatibility between the polysiloxane and the naphthoquinone diazide compound or coloring due to the decomposition of the quinone diazide compound occurring during thermal curing is produced. The additive amount of the naphthoquinone diazide compound is preferably 15 parts by weight or less in order to attain a film with higher transparency.

The positive photosensitive composition of the present invention contains (c) a solvent. The solvent to be used is not particularly limited, but compounds having an alcoholic hydroxyl group are preferably used. When these solvents are used, polysiloxane and the quinone diazide compound are uniformly dissolved, and even after the composition is applied to form a film, the film can achieve high transparency without being whitened.

The compounds having an alcoholic hydroxyl group are not particularly limited, but they are preferably compounds having a boiling point of 110 to 250° C. under an atmospheric pressure. When the boiling point is higher than 250° C., an amount of a solvent remaining in the film increases and film shrinkage in curing the film increases, and good flatness is not achieved. On the other hand, when the boiling point is lower than 110° C., because drying in coating is too fast, coatability is deteriorated, for example, a film surface is roughened.

Specific examples of the compounds having an alcoholic hydroxyl group include acetol, 3-hydroxy-3-methyl-2-butanone, 4-hydroxy-3-methyl-2-butanone, 5-hydroxy-2-pentanone, 4-hydroxy-4-methyl-2-pentanone (diacetone alcohol), ethyl lactate, butyl lactate, propylene glycol monomethyl ether, propylene glycol monoethyl ether, propylene glycol mono-n-propyl ether, propylene glycol mono-n-butyl ether, propylene glycol mono-t-butyl ether, diethylene glycol monomethyl ether, diethylene glycol monoethyl ether, dipropylene glycol monomethyl ether, dipropylene glycol monoethyl ether, 3-methoxy-1-butanol, and 3-methyl-3-methoxy-1-butanol. These compounds having an alcoholic hydroxyl group may be used singly or may be used in combination of two or more species thereof.

The photosensitive composition of the present invention may contain other solvents as long as the solvent does not impair an effect of the present invention. Examples of other solvents include esters such as ethyl acetate, n-propyl acetate, isopropyl acetate, n-butyl acetate, isobutyl acetate, propylene glycol monomethyl ether acetate, 3-methoxy-1-butyl acetate, 3-methyl-3-methoxy-1-butyl acetate, and ethyl acetoacetate; ketones such as methyl isobutyl ketone, diisopropyl ketone, diisobutyl ketone, and acetylacetone; ethers such as diethyl ether, diisopropyl ether, di-n-butyl ether, diphenyl ether, diethylene glycol ethyl methyl ether, and diethylene glycol dimethyl ether; and γ-butyrolactone, γ-valerolactone, δ-valerolactone, propylene carbonate, N-methylpyrrolidone, cyclopentanone, cyclohexanone and cycloheptanone.

An additive amount of the solvent is not particularly limited, but it is preferably within a range of 100 to 2000 parts by weight with respect to 100 parts by weight of a resin (polysiloxane).

Moreover, the photosensitive composition of the present invention can also contain additives such as a silane coupling agent, a crosslinking agent, a crosslinking promoter, a sensitizer, a thermal radical generating agent, a solubility enhancer, a dissolution inhibitor, a surfactant, a stabilizer and an antifoaming agent as required.

The photosensitive composition of the present invention may contain a silane coupling agent. When the photosensitive composition of the present invention contains a silane coupling agent, the adhesion of the photosensitive composition to a substrate is improved.

Specific examples of the silane coupling agent include methyltrimethoxysilane, methyltriethoxysilane, dimethyldimethoxysilane, dimethyldiethoxysilane, ethyltrimethoxysilane, ethyltriethoxysilane, n-propyltrimethoxysilane, n-propyltriethoxysilane, n-butyltrimethoxysilane, n-butyltriethoxysilane, phenyltrimethoxysilane, phenyltriethoxysilane, diphenyldimethoxysilane, diphenyldiethoxysilane, vinyltrimethoxysilane, vinyltriethoxysilane, 3-methacryloxypropyltrimethoxysilane, 3-methacryloxypropyltriethoxysilane, 3-methacryloxypropylmethyldimethoxysilane, 3-methacryloxypropylmethyldiethoxysilane, 3-acryloxypropyltrimethoxysilane, 3-aminopropyltrimethoxysilane, 3-aminopropyltriethoxysilane, 3-triethoxysilyl-N-(1,3-dimethyl-butylidene)propylamine, N-phenyl-3-aminopropyltrimethoxysilane, 3-glycidoxypropyltrimethoxysilane, 3-glycidoxypropyltriethoxysilane, 3-glycidoxypropylmethyldiethoxysilane, 2-(3,4-epoxycyclohexyl)ethyltrimethoxysilane, 2-(3,4-epoxycyclohexyl)ethyltriethoxysilane, [(3-ethyl-3-oxetanyl)methoxy]propyltrimethoxysilane, [(3-ethyl-3-oxetanyl)methoxy]propyltriethoxysilane, 3-mercaptopropyltrimethoxysilane, 3-mercaptopropylmethyldimethoxysilane, 3-ureidopropyltriethoxysilane, 3-isocyanatepropyltriethoxysilane, 3-trimethoxysilylpropylsuccinic acid and N-t-butyl-3-(3-trimethoxysilylpropyl)succinimide.

An additive amount of the silane coupling agent is not particularly limited, but it is preferably within a range of 0.1 to 10 parts by weight with respect to 100 parts by weight of a resin (acrylic resin+polysiloxane). When the additive amount is less than 0.1 parts by weight, the effect of improving adhesion is not adequate, and when the additive amount is more than 10 parts by weight, a condensation reaction occurs within the silane coupling agent during storage, causing development residue at the time of development.

The photosensitive composition of the present invention may contain a surfactant. When the composition contains the surfactant, application unevenness can be remedied and a uniform coating film can be obtained. Fluorine-based surfactants and silicone-based surfactants are preferably used as the surfactant.

Specific examples of the fluorine-based surfactants include fluorine-based surfactants formed of compounds respectively having a fluoroalkyl or fluoroalkylene group at least at any of the ends, main chain and side chains thereof such as 1,1,2,2-tetrafluorooctyl(1,1,2,2-tetrafluoropropyl)ether, 1,1,2,2-tetrafluorooctylhexyl ether, octaethylene glycol di(1,1,2,2-tetrafluorobutyl)ether, hexaethylene glycol (1,1,2,2,3,3-hexafluoropentyl)ether, octapropylene glycol di(1,1,2,2-tetrafluorobutyl)ether, hexapropylene glycol di(1,1,2,2,3,3-hexafluoropentyl)ether, sodium perfluorododecylsulfonate, 1,1,2,2,8,8,9,9,10,10-decafluorododecane, 1,1,2,2,3,3-hexafluorodecane, N-[3-(perfluorooctanesulfonamide)propyl]-N,N′-dimethyl-N-ca rboxymethylene-ammonium betaine, perfluoroalkylsulfonamide propyltrimethylammonium salt, perfluoroalkyl-N-ethylsulfonylglycine salt, bis(N-perfluorooctylsulfonyl-N-ethylaminoethyl)phosphate and monoperfluoroalkyl ethylphosphoric acid ester. Further, commercially available fluorine-based surfactants include Megafac F142D, Megafac F172, Megafac F173, Megafac F183, and Megafac F475 (all produced by Dainippon Ink and Chemicals, Inc.), Eftop EF301, Eftop EF303, and Eftop EF352 (all produced by Shin-Akita Kasei K.K.), Fluorad FC-430 and Fluorad FC-431 (both produced by Sumitomo 3M Ltd.), Asahi Guard AG710, Surflon S-382, Surflon SC-101, Surflon SC-102, Surflon SC-103, Surflon SC-104, Surflon SC-105, and Surflon SC-106 (all produced by Asahi Glass Co., Ltd.), BM-1000 and BM-1100 (all produced by Yusho Co., Ltd.), NBX-15, FTX-218, and DFX-218 (all produced by NEOS Co., Ltd.), and the like.

Commercially available silicone-based surfactants include SH28PA, SH7PA, SH21PA, SH30PA, and ST94PA (all produced by Down Corning Toray Co., Ltd.), BYK-333 (produced by BYK Japan KK), and the like.

Generally, the content of the surfactant is 0.0001 to 1% by weight with respect to the amount of the photosensitive composition.

The photosensitive composition of the present invention may contain a crosslinking agent. The crosslinking agent is a compound which crosslinks an acrylic resin or polysiloxane at the time of thermal curing and is incorporated into a resin, and a degree of crosslinking of the cured film is enhanced by containing the crosslinking agent. Thereby, the chemical resistance of the cured film is improved and the reduction in resolution of patterns due to pattern reflow during thermal curing is inhibited.

The crosslinking agent is not particularly limited, but preferable examples of the crosslinking agent include compounds having two or more structures selected from the group consisting of groups represented by the general formula (7), an epoxy structure and an oxetane structure. A combination of the above-mentioned structures is not particularly limited, but structures to be selected are preferably the same.

[Chem. 11]

CH₂—O—R¹⁷) (7)

In the compounds having two or more groups represented by the general formula (7), R¹⁷ represents either hydrogen or an alkyl group having 1 to 10 carbon atoms. Further, plural R¹⁷s in the compound may be the same or different. Specific examples of the alkyl group include a methyl group, an ethyl group, an n-propyl group, an isopropyl group, an n-butyl group, a t-butyl group, an n-hexyl group, and an n-decyl group.

Specific examples of the compounds having two or more groups represented by the general formula (7) include the following melamine derivatives and urea derivatives (trade name, produced by SANWA CHEMICAL CO., LTD.).

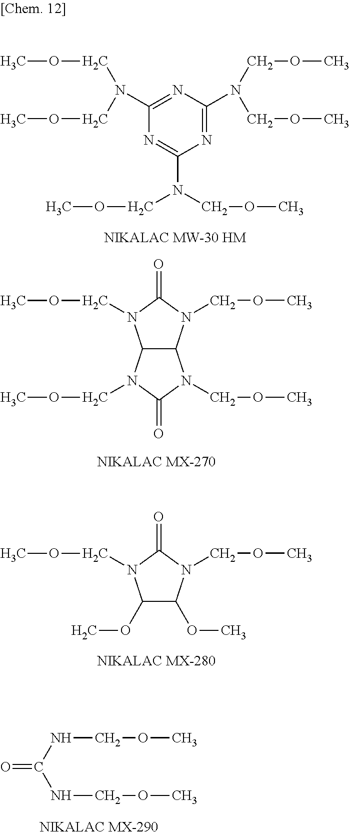

Specific examples of the compounds having two or more epoxy structures or oxetane structures include “Epolite” 40E, “Epolite” 100E, “Epolite” 200E, “Epolite” 400E, “Epolite” 70P, “Epolite” 200P, “Epolite” 400P, “Epolite” 1500NP, “Epolite” 80MF, “Epolite” 4000, and “Epolite” 3002 (these are trade names, produced by Kyoeisha Chemical Co., Ltd.), “DENACOL” EX-212L, “DENACOL” EX-214L, “DENACOL” EX-216L, “DENACOL” EX-850L, and “DENACOL” EX-321L (these are trade names, produced by Nagase ChemteX Corp.), GAN, GOT, EPPN 502H, NC 3000, and NC 6000 (these are trade names, produced by Nippon Kayaku Co., Ltd.), “EPICOAT” 828, “EPICOAT” 1002, “EPICOAT” 1750, “EPICOAT” 1007, YX8100-BH30, E1256, E4250, and E4275 (these are trade names, produced by Japan Epoxy Resins Co., Ltd.), “EPICLON” EXA-9583, “EPICLON” HP4032, “EPICLON” N695, and “EPICLON” HP7200 (these are trade names, produced by Dainippon Ink and Chemicals, Inc.), “TEPIC” S, “TEPIC” G, and “TEPIC” P (these are trade names, produced by Nissan Chemical Industries, Ltd.), and “EPOTOHTO” YH-434L (trade name, produced by TOHTO KASEI CO., LTD.).

In addition, the above-mentioned crosslinking agents may be used singly or may be used in combination of two or more species thereof.

An additive amount of the crosslinking agent is not particularly limited, but it is preferably within a range of 0.1 to 20 parts by weight with respect to 100 parts by weight of a resin (polysiloxane+acrylic resin). When the additive amount of the crosslinking agent is less than 0.1 parts by weight, crosslinking of the resin is insufficient and the effect of the crosslinking agent is small. On the other hand, when the additive amount of the crosslinking agent is more than 20 parts by weight, the transparent and colorless property of the cured film is deteriorated, or the storage stability of the composition is deteriorated.

The photosensitive composition of the present invention may contain a crosslinking promoter. The crosslinking promoter is a compound that promotes the crosslinking of the polysiloxane at the time of thermal curing, and a thermal acid generator to generate an acid at the time of thermal curing or a photo acid generator to generate an acid at the time of bleaching exposure prior to thermal curing is used as the crosslinking promoter. When the acid is present in the film at the time of thermal curing, a condensation reaction of an unreacted silanol group in the polysiloxane is promoted and a degree of crosslinking of the cured film is increased. Thereby, the chemical resistance of the cured film is improved and the reduction in resolution of patterns due to pattern reflow during thermal curing is inhibited.

The thermal acid generator used in the present invention is a compound that generates an acid at the time of thermal curing. The thermal acid generator preferably does not generate an acid or generates only a small amount of acid at the time of prebaking after application of the composition. Therefore, the thermal acid generator is preferably a compound that generates an acid at a prebaking temperature or higher, for example, at 100° C. or higher. If an acid is generated at a prebaking temperature or lower, crosslinking of the polysiloxane tends to occur during prebaking and therefore sensitivity may be deteriorated or development residue may be produced at the time of development.

Specific examples of the thermal acid generator preferably used include “San-Aid” SI-60, SI-80, SI-100, SI-200, SI-110, SI-145, SI-150, SI-60L, SI-80L, SI-100L, SI-110L, SI-145L, SI-150L, SI-160L and SI-180L (these are trade names, produced by Sanshin Chemical Industry Co., Ltd.), 4-hydroxyphenyldimethylsulfonium trifluoromethanesulfonate, benzyl-4-hydroxyphenylmethylsulfonium trifluoromethanesulfonate, 2-methylbenzyl-4-hydroxyphenylmethylsulfonium trifluoromethanesulfonate, 4-acetoxyphenyldimethylsulfonium trifluoromethanesulfonate, 4-acetoxyphenylbenzylmethylsulfonium trifluoromethanesulfonate, 4-methoxycarbonyloxyphenyldimethylsulfonium trifluoromethanesulfonate, and benzyl-4-methoxycarbonyloxyphenylmethylsulfonium trifluoromethanesulfonate (these are trade names, produced by Sanshin Chemical Industry Co., Ltd.). Further, these compounds may be used singly or may be used in combination of two or more species thereof.

The photo acid generator used in the present invention is a compound which generates an acid at the time of bleaching exposure and generates an acid by irradiation of a ray with an exposure wavelength of 365 nm (i-beam), 405 nm (h-beam) or 436 nm (g-beam), or irradiation of a mixed ray thereof. Therefore, there is a possibility that an acid is generated also in pattern exposure in which a similar light source is used, but since an exposure amount of the pattern exposure is smaller than that of bleaching exposure, only a small amount of acid is produced and this does not cause a problem. Further, the acid to be generated is preferably a strong acid such as perfluoroalkylsulfonic acid or p-toluenesulfonic acid. A quinone diazide compound that generates a carboxylic acid does not have a function of the photo acid generator referred to herein and is different from the crosslinking promoter in the present invention.

Specific examples of the photo acid generator preferably used include SI-100, SI-101, SI-105, SI-106, SI-109, PI-105, PI-106, PI-109, NAI-100, NAI-1002, NAI-1003, NAI-1004, NAI-101, NAI-105, NAI-106, NAI-109, NDI-101, NDI-105, NDI-106, NDI-109, PAI-01, PAI-101, PAI-106 and PAI-1001 (these are trade names, produced by Midori Kagaku Co., Ltd.), SP-077 and SP-082 (these are trade names, produced by ADEKA Corp.), TPS-PFBS (trade name, produced by Toyo Gosei Co., Ltd.), CGI-MDT and CGI-NIT (these are trade names, produced by Ciba Specialty Chemicals Inc.), and WPAG-281, WPAG-336, WPAG-339, WPAG-342, WPAG-344, WPAG-350, WPAG-370, WPAG-372, WPAG-449, WPAG-469, WPAG-505 and WPAG-506 (these are trade names, produced by Wako Pure Chemical Industries, Ltd.). Further, these compounds may be used singly or may be used in combination of two or more species thereof.

Further, as the crosslinking promoter, the thermal acid generator can also be used in conjunction with the photo acid generator. An additive amount of the crosslinking promoter is not particularly limited, but it is preferably within a range of 0.01 to 5 parts by weight with respect to 100 parts by weight of a resin (polysiloxane). When the additive amount is less than 0.01 parts by weight, the effect of crosslinking is not adequate, and when the additive amount is more than 5 parts by weight, the crosslinking of the polysiloxane may occur during prebaking or pattern exposure.

The photosensitive composition of the present invention may contain a sensitizer. When a sensitizer is contained, a reaction of the naphthoquinone diazide compound as a photosensitizing agent is promoted to increase sensitivity, and when a photo acid generator is contained as a crosslinking promoter, a reaction at the time of bleaching exposure is promoted to increase the solvent resistance and the resolution of patterns of the cured film are improved.

The sensitizer to be used in the present invention is not particularly limited, but a sensitizer which is vaporized by heat treatment and/or discolored by light irradiation is preferably used. This sensitizer needs to exhibit absorption at a wavelength of 365 nm (i-beam), 405 nm (h-beam) or 436 nm (g-beam) which is a wavelength of alight source in the pattern exposure or the bleaching exposure, but if the sensitizer remains as-is in a cured film, a transparent and colorless property of a cured film is deteriorated because an absorption wavelength is present in a visible light region. Therefore, in order to prevent the reduction in the transparent and colorless property due to the sensitizer, the sensitizer to be used is preferably a compound (sensitizer) which is vaporized by heat treatment such as thermal curing and/or discolored by light irradiation such as bleaching exposure.

Specific examples of the sensitizer which is vaporized by heat treatment and/or discolored by light irradiation include coumarins such as 3,3′-carbonylbis(diethylaminocoumarin); anthraquinones such as 9,10-anthraquinone; aromatic ketones such as benzophenone, 4,4′-dimethoxybenzophenone, acetophenone, 4-methoxyacetophenone, and benzaldehyde; and condensed aromatics such as biphenyl, 1,4-dimethylnaphthalene, 9-fluorenone, fluorene, phenanthrene, triphenylene, pyrene, anthracene, 9-phenylanthracene, 9-methoxyanthracene, 9,10-diphenylanthracene, 9,10-bis(4-methoxyphenyl)anthracene, 9,10-bis(triphenylsilyl)anthracene, 9,10-dimethoxyanthracene, 9,10-diethoxyanthracene, 9,10-dipropoxyanthracene, 9,10-dibutoxyanthracene, 9,10-dipentaoxyanthracene, 2-t-butyl-9,10-dibutoxyanthracene and 9,10-bis(trimethylsilylethynyl)anthracene.

Among these sensitizers, a sensitizer which is vaporized by heat treatment is preferably a sensitizer which is sublimated, evaporated or thermally decomposed by heat treatment and a thermally decomposed product of which is sublimated or evaporated by heat treatment. The vaporization temperature of the sensitizer is preferably 130 to 400° C. and more preferably 150 to 250° C. When the vaporization temperature of the sensitizer is lower than 130° C., there may be cases where the sensitizer is vaporized during prebaking and is not present in an exposure process, and therefore the sensitivity is not increased. Further, the vaporization temperature of the sensitizer is preferably 150° C. or higher in order to suppress the vaporization during prebaking as far as possible. On the other hand, when the vaporization temperature of the sensitizer is higher than 400° C., there may be cases where the sensitizer is not vaporized at the time of thermal curing to remain in a cured film, causing the transparent and colorless property to deteriorate. In order to completely vaporize the sensitizer at the time of thermal curing, the vaporization temperature of the sensitizer is preferably 250° C. or lower.

On the other hand, the sensitizer which is discolored by light irradiation is preferably a sensitizer in which absorption in a visible light region is discolored by light irradiation. Further, a more preferable compound which is discolored by light irradiation is a compound which is dimerized by light irradiation. When the sensitizer is dimerized by light irradiation, since the molecular weight of the sensitizer is increased and the sensitizer becomes insoluble, the effects of improving chemical resistance and heat resistance and reducing an amount of an extract from the transparent cured film are achieved.

Further, the sensitizer is preferably an anthracene-based compound since this compound can achieve high sensitivity and is dimerized and discolored by light irradiation, and further the sensitizer is preferably a 9,10-disubstituted anthracene-based compound since the anthracene-based compound in which 9th and 10th positions thereof are occupied by a hydrogen atom is thermally unstable. Moreover, the sensitizer is preferably a 9,10-dialkoxy anthracene-based compound represented by the general formula (8) from the viewpoint of improvement in solubility of the sensitizer and the reactivity of a photodimerization reaction.

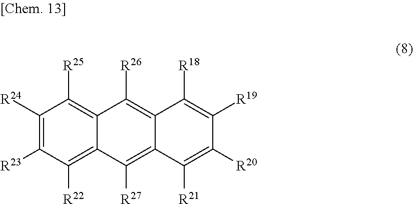

R¹⁸ to R²⁵ in the general formula (8) independently represent hydrogen, an alkyl group having 1 to 20 carbon atoms, an alkoxy group, an alkenyl group, an aryl group, an acyl group and an organic group replaced with them. Specific examples of the alkyl group include a methyl group, an ethyl group and an n-propyl group. Specific examples of the alkoxy group include a methoxy group, an ethoxy group, a propoxy group, a butoxy group and a pentyloxy group. Specific examples of the alkenyl group include a vinyl group, an acryloxypropyl group and a methacryloxypropyl group. Specific examples of the aryl group include a phenyl group, a tolyl group and a naphthyl group. Specific examples of the acyl group include an acetyl group. R¹⁸ to R²⁵ are preferably hydrogen or an organic group having 1 to 6 carbon atoms in view of the volatility of a compound and the reactivity of photodimerization. Moreover, R¹⁸, R²¹, R²² and R²⁵ are more preferably hydrogen.

R²⁶ and R²⁷ in the general formula (8) represent an alkoxy group having 1 to 20 carbon atoms and an organic group replaced therewith. Specific examples of the alkoxy group include a methoxy group, an ethoxy group, a propoxy group, a butoxy group and a pentyloxy group, but the alkoxy group is preferably a propoxy group or a butoxy group in view of solubility of a compound and a discoloration reaction through photodimerization.

An additive amount of the sensitizer is not particularly limited, but the sensitizer is preferably added in an amount within a range of 0.01 to 5 parts by weight with respect to 100 parts by weight of a resin (polysiloxane). When the additive amount of the sensitizer falls outside this range, the transparency of the cured film is deteriorated or the sensitivity is deteriorated.

The photosensitive composition of the present invention may contain an acrylic resin. The adhesion of the composition to an underlaid substrate and pattern-processability are sometimes improved by using the acrylic resin. The acrylic resin is not particularly limited, and preferable examples thereof include polymers of an unsaturated carboxylic acid. Examples of the unsaturated carboxylic acid include an acrylic acid, a methacrylic acid, an itaconic acid, a crotonic acid, a maleic acid, a fumaric acid and the like. These unsaturated carboxylic acids may be used singly or may be used in combination with another copolymerizable ethylenically unsaturated compound. Examples of the copolymerizable ethylenically unsaturated compound include methyl acrylate, methyl methacrylate, ethyl acrylate, ethyl methacrylate, n-propyl acrylate, n-propyl methacrylate, isopropyl acrylate, isopropyl methacrylate, n-butyl acrylate, n-butyl methacrylate, sec-butyl acrylate, sec-butyl methacrylate, isobutyl acrylate, isobutyl methacrylate, t-butyl acrylate, t-butyl methacrylate, n-pentyl acrylate, n-pentyl methacrylate, 2-hydroxyethyl acrylate, 2-hydroxyethyl methacrylate, glycidyl acrylate, glycidyl methacrylate, benzyl acrylate, benzyl methacrylate, styrene, p-methylstyrene, o-methylstyrene, m-methylstyrene, α-methylstyrene, tricyclo[5.2.1.0^{2.6}]decane-8-yl acrylate, tricyclo[5.2.1.0^{2.6}]decane-8-yl methacrylate and the like.

Further, the weight average molecular weight (Mw) of the acrylic resin is not particularly limited, but it is preferably 5000 to 50000 on the polystyrene equivalent basis measured by GPC, and more preferably 8000 to 35000. When the Mw is less than 5000, the reflow of the pattern occurs at the time of thermal curing and resolution is deteriorated. On the other hand, when the Mw is more than 50000, since phase separation occurs between the polysiloxane and the acrylic resin, and this makes the film cloudy and deteriorates the transmittance of the cured film.

The acrylic resin to be used in the present invention is preferably alkali-soluble, and the acid value of the acrylic resin is preferably 50 to 150 mg KOH/g and more preferably 70 to 130 mg KOH/g. When the acid value of the acrylic resin is less than 50 mg KOH/g, development residue tends to be produced at the time of development. On the other hand, when the acid value of the acrylic resin is more than 150 mg KOH/g, film loss of an unexposed area increases at the time of development increases.

Further, the acrylic resin is preferably an acrylic resin having an ethylenically unsaturated group added to its side chain. When an ethylenically unsaturated group is added to the side chain of the acrylic resin, crosslinking of the acrylic resin occurs at the time of thermal curing and the chemical resistance of the cured film is improved. Examples of the ethylenically unsaturated group include a vinyl group, an allyl group, an acrylic group, and a methacryl group. Examples of a method of adding an ethylenically unsaturated group to the side chain of the acrylic resin include a method in which a compound containing a functional group such as a hydroxyl group, an amino group or a glycidyl group, and an ethylenically unsaturated group is used and the functional group is reacted with a carbonyl group in the acrylic resin. Examples of the compound containing a functional group such as a hydroxyl group, an amino group or a glycidyl group, and an ethylenically unsaturated group, referred to herein, include 2-hydroxyethyl acrylate, 2-hydroxyethyl methacrylate, 2-aminoethyl acrylate, 2-aminoethyl methacrylate, glycidyl acrylate and glycidyl methacrylate.

A method of forming a cured film by use of the photosensitive composition of the present invention will be described. The photosensitive composition of the present invention is applied onto a base substrate by a publicly known method such as a spinner or a slit and prebaked by a heating apparatus such as a hot plate or an oven. The prebake is preferably carried out at a temperature of 50 to 150° C. for 30 seconds to 30 minutes to form a film having a thickness of 0.1 to 15 μm after the prebake.

After completion of prebaking, the film is patterned and exposed through a desired mask at about 10 to about 4000 J/m² (on the exposure amount at wavelength 365 nm equivalent basis) with an ultraviolet and visible light exposure machine such as a stepper, a mirror projection mask aligner (MPA) or a parallel light mask aligner (PLA).

After exposure, an exposed area can be dissolved by development to obtain a positive pattern. As a development method, it is preferred to employ a method in which the exposed photosensitive composition is immersed in a developer for 5 seconds to 10 minutes by a method such as showering, dipping or paddling. As the developer, publicly known alkaline developers can be employed. Specific examples of the alkaline developers include aqueous solutions containing one or more kinds of inorganic alkalis such as hydroxide, carbonate, phosphate, silicate and borate of alkali metals, amines such as 2-diethylaminoethanol, monoethanolamine, and diethanolamine, and quaternary ammonium salts such as tetramethylammonium hydroxide and choline. A cured film is preferably rinsed with water after development, and as required, the cured film can also be dehydrated, dried and baked at a temperature of 50 to 150° C. in a heating apparatus such as a hot plate or an oven.

Thereafter, bleaching exposure is preferably performed. By performing bleaching exposure, an unreacted naphthoquinone diazide compound remaining in the film is photo-decomposed to further improve the optical transparency of the film. Examples of a method of bleaching exposure include a method in which the entire surface of the developed film is exposed to ultraviolet light at about 100 to about 20000 J/m² (on the exposure amount at wavelength 365 nm equivalent basis) with an ultraviolet and visible light exposure machine such as a PLA.

The film subjected to bleaching exposure, if required, is soft-baked at a temperature of 50 to 150° C. for 30 seconds to 30 minutes with a heating apparatus such as a hot plate or an oven, and then is cured at a temperature of 150 to 450° C. for about 1 hour with a heating apparatus such as a hot plate or an oven, and thereby, a cured film, such as a planarization film for a TFT in a display device, an interlayer insulation film in a semiconductor device, or a core or clad material in a light waveguide, is formed. In recent years, it is desired to form a Si film or a SiN film on the cured film at 280° C. or higher by a high temperature CVD method, and high heat resistance and high transparency which stand this high temperature are desired.

In the cured film prepared by using the photosensitive composition of the present invention, the light transmittance per a film thickness of 3 μm at a wavelength of 400 nm is 90% or more, preferably 92% or more, and more preferably 95% or more. If the light transmittance of the cured film is lower than 90%, when the cured film is used as a planarization film for a TFT substrate of a liquid crystal display device, backlight changes in color at the time of passing through the planarization film and takes on a yellow tinge in white display.

The transmittance per a film thickness of 3 μm at a wavelength of 400 nm is determined by the following method. The composition is applied onto a Tempax glass sheet by spin-coating at an arbitrary rotating speed by using a spin coater, and the applied composition is pre-baked at 100° C. for 2 minutes with a hot plate. Thereafter, as bleaching exposure, the entire surface of the film is exposed to an ultra high pressure mercury lamp at 3000 J/m² (on the exposure amount at wavelength 365 nm equivalent basis) by using a PLA and the exposed film is thermally cured at 220° C. for 1 hour in the air with an oven to prepare a cured film having a thickness of 3 μm. The ultraviolet and visible absorption spectra of the obtained cured film are measured with Multi Spec-1500 manufactured by Shimadzu Corporation to determine a transmittance at a wavelength of 400 nm.

This cured film is suitably used for a planarization film for a TFT in a display device, an interlayer insulation film in a semiconductor device, an insulation film/protective film for a touch panel, or a core or clad material in a light waveguide.

The device in the present invention refers to a display device, a semiconductor device and materials for a light waveguide, having the above-mentioned cured film having high heat resistance and high transparency, and is particularly suitable for a liquid crystal display device, an organic EL display device and a display device with a sensor element for a touch panel, which have the cured film as a planarization film for a TFT.

### EXAMPLES

Hereinafter, the present invention will be described in more detail by way of examples, but the present invention is not limited to these examples. Further, compounds, for which an abbreviation is used, of the compounds used in examples are shown below.

DAA: Diacetone alcohol
PGMEA: Propylene glycol monomethyl ether acetate

### GBL: Gamma-butyrolactone

EDM: Diethylene glycol methyl ethyl ether
DPM: Dipropylene glycol monoether methyl

Further, the solid content concentration of the polysiloxane solution and the acrylic resin solution, and the weight average molecular weight (Mw) of the siloxane and the acrylic resin were determined according to the following methods.

(1) Solid Content Concentration

1 g of a polysiloxane solution or an acrylic resin solution was weighed, put in an aluminum cup, and heated at 250° C. for 30 minutes by use of a hot plate to evaporate a liquid content. A solid content left in the heated aluminum cup was weighed to determine the solid content concentration of the acrylic resin solution or the polysiloxane solution.

(2) Weight Average Molecular Weight

The weight average molecular weight was determined on the polystyrene equivalent basis by GPC (410 type RI detector manufactured by Waters Corp., fluid bed: tetrahydrofuran).

(3) Ratio Between the Organosilane Structures Represented by the General Formulas (1) and (2) in the Polysiloxane

Measurement of ²⁹Si-NMR was performed, and a proportion of a value of integral of each organosilane was determined from a value of overall integral and the ratio was calculated.

A specimen (liquid) was put in a Teflon (registered trademark) NMR sample tube with a diameter of 10 mm and used for measurement. Measurement conditions of ²⁹Si—NMR are shown below.

Apparatus: JNM GX-270 manufactured by JEOL Ltd., measurement method: gated decoupling method

Measurement nucleus frequency: 53.6693 MHz (²⁹Si nucleus), spectrum width: 20000 Hz

Pulse width: 12 μsec (45° pulse), pulse repetition time: 30.0 sec

Solvent: acetone-d6, reference material: tetramethylsilane

Measurement temperature: room temperature, sample rotating speed: 0.0 Hz

### Synthesis Example 1 Synthesis of Polysiloxane Solution (a)

Into a 500 mL three-necked flask, 40.86 g (0.30 mol) of methyltrimethoxysilane, 99.15 g (0.5 mol) of phenyltrimethoxysilane, 12.32 g (0.05 mol) of 2-(3,4-epoxycyclohexyl)ethyltrimethoxysilane, 17.63 g (0.15 mol) of M Silicate 51 ((m=4, average) produced by TAMA CHEMICALS CO., LTD.) and 170.77 g of PGMEA were charged, and to the resulting mixture, an aqueous phosphoric acid solution having 0.51 g (0.3% by weight with respect to the weight of charged monomers) of phosphoric acid dissolved in 53.55 g of water was added over 10 minutes while stirring the mixture at room temperature. Thereafter, the flask was immersed in an oil bath of 40° C., the resulting mixture was stirred for 30 minutes, and then the oil bath was heated up to 115° C. over 30 minutes. The temperature of the solution reached 100° C. after a lapse of 1 hour from the start of heating and the solution was heated and stirred for further 2 hours (the temperature of the solution was 100 to 110° C. in the meantime) to obtain a polysiloxane solution (a). In addition, a nitrogen gas was flowed at a flow rate of 0.05 l (liter)/min during the heating and stirring. During the reaction, 125 g in total of methanol and water as by-products were distilled out.

The obtained polysiloxane solution (a) had a solid content concentration of 43% by weight and the polysiloxane had a weight average molecular weight of 8500. In addition, the content ratio of the organosilane represented by the general formula (1) in the polysiloxane was 50% in terms of the mole ratio of Si atoms, and the content ratio of the organosilane represented by the general formula (2) in the polysiloxane was 15% in terms of the mole ratio of Si atoms.

### Synthesis Example 2 Synthesis of Polysiloxane Solution (b)

Into a 500 mL three-necked flask, 24.52 g (0.18 mol) of methyltrimethoxysilane, 118.98 g (0.60 mol) of phenyltrimethoxysilane, 14.78 g (0.06 mol) of 2-(3,4-epoxycyclohexyl)ethyltrimethoxysilane, 42.30 g (0.36 mol) of M Silicate 51 ((m=4, average) produced by TAMA CHEMICALS CO., LTD.) and 181.89 g of PGMEA were charged, and to the resulting mixture, an aqueous phosphoric acid solution having 0.60 g (0.3% by weight with respect to the weight of charged monomers) of phosphoric acid dissolved in 62.64 g of water was added over 10 minutes while stirring the mixture at room temperature. Thereafter, the flask was immersed in an oil bath of 40° C., the resulting mixture was stirred for 30 minutes, and then the oil bath was heated up to 115° C. over 30 minutes. The temperature of the solution reached 100° C. after a lapse of 1 hour from the start of heating and the solution was heated and stirred for further 2 hours (the temperature of the solution was 100 to 110° C. in the meantime) to obtain a polysiloxane solution (b). In addition, a nitrogen gas was flowed at a flow rate of 0.05 l (liter)/min during the heating and stirring. During the reaction, 150 g in total of methanol and water as by-products were distilled out.

The obtained polysiloxane solution (b) had a solid content concentration of 44% by weight and the polysiloxane had a weight average molecular weight of 11400. In addition, the content ratio of the organosilane represented by the general formula (1) in the polysiloxane was 50% in terms of the mole ratio of Si atoms, and the content ratio of the organosilane represented by the general formula (2) in the polysiloxane was 30% in terms of the mole ratio of Si atoms.

### Synthesis Example 3 Synthesis of Polysiloxane Solution (c)

Into a 500 mL three-necked flask, 4.77 g (0.035 mol) of methyltrimethoxysilane, 69.41 g (0.35 mol) of phenyltrimethoxysilane, 8.62 g (0.035 mol) of 2-(3,4-epoxycyclohexyl)ethyltrimethoxysilane, 32.90 g (0.28 mol) of M Silicate 51 ((m=4, average) produced by TAMA CHEMICALS CO., LTD.) and 104.8 g of PGMEA were charged, and to the resulting mixture, an aqueous phosphoric acid solution having 0.69 g (0.6% by weight with respect to the weight of charged monomers) of phosphoric acid dissolved in 35.91 g of water was added over 10 minutes while stirring the mixture at room temperature. Thereafter, the flask was immersed in an oil bath of 40° C., the resulting mixture was stirred for 30 minutes, and then the oil bath was heated up to 115° C. over 30 minutes. The temperature of the solution reached 100° C. after a lapse of 1 hour from the start of heating and the solution was heated and stirred for further 4 hours (the temperature of the solution was 100 to 110° C. in the meantime) to obtain a polysiloxane solution (c). In addition, a nitrogen gas was flowed at a flow rate of 0.05 l (liter)/min during the heating and stirring. During the reaction, 97 g in total of methanol and water as by-products were distilled out.

The obtained polysiloxane solution (c) had a solid content concentration of 42% by weight and the polysiloxane had a weight average molecular weight of 12400. In addition, the content ratio of the organosilane represented by the general formula (1) in the polysiloxane was 50% in terms of the mole ratio of Si atoms, and the content ratio of the organosilane represented by the general formula (2) in the polysiloxane was 40% in terms of the mole ratio of Si atoms.

### Synthesis Example 4 Synthesis of Polysiloxane Solution (d)

Into a 500 mL three-necked flask, 99.15 g (0.50 mol) of phenyltrimethoxysilane, 58.75 g (0.50 mol) of M Silicate 51 ((m=4, average) produced by TAMA CHEMICALS CO., LTD.) and 158.59 g of DAA were charged, and to the resulting mixture, an aqueous phosphoric acid solution having 0.79 g (0.5% by weight with respect to the weight of charged monomers) of phosphoric acid dissolved in 49.5 g of water was added over 10 minutes while stirring the mixture at room temperature. Thereafter, the flask was immersed in an oil bath of 40° C., the resulting mixture was stirred for 30 minutes, and then the oil bath was heated up to 115° C. over 30 minutes. The temperature of the solution reached 100° C. after a lapse of 1 hour from the start of heating and the solution was heated and stirred for further 4 hours (the temperature of the solution was 100 to 110° C. in the meantime) to obtain a polysiloxane solution (d). In addition, a nitrogen gas was flowed at a flow rate of 0.05 l (liter)/min during the heating and stirring. During the reaction, 123 g in total of methanol and water as by-products were distilled out.

The obtained polysiloxane solution (d) had a solid content concentration of 39% by weight and the polysiloxane had a weight average molecular weight of 13500. In addition, the content ratio of the organosilane represented by the general formula (1) in the polysiloxane was 50% in terms of the mole ratio of Si atoms, and the content ratio of the organosilane represented by the general formula (2) in the polysiloxane was 50% in terms of the mole ratio of Si atoms.

### Synthesis Example 5 Synthesis of Polysiloxane Solution (e)

Into a 500 mL three-necked flask, 79.32 g (0.40 mol) of phenyltrimethoxysilane, 70.50 g (0.60 mol) of M Silicate 51 ((m=4, average) produced by TAMA CHEMICALS CO., LTD.) and 118.96 g of DAA were charged, and to the resulting mixture, an aqueous phosphoric acid solution having 0.90 g (0.6% by weight with respect to the weight of charged monomers) of phosphoric acid dissolved in 48.60 g of water was added over 10 minutes while stirring the mixture at room temperature. Thereafter, the flask was immersed in an oil bath of 40° C., the resulting mixture was stirred for 30 minutes, and then the oil bath was heated up to 115° C. over 30 minutes. The temperature of the solution reached 100° C. after a lapse of 1 hour from the start of heating and the solution was heated and stirred for further 4 hours (the temperature of the solution was 100 to 110° C. in the meantime) to obtain a polysiloxane solution (e). In addition, a nitrogen gas was flowed at a flow rate of 0.05 l (liter)/min during the heating and stirring. During the reaction, 135 g in total of methanol and water as by-products were distilled out.

The obtained polysiloxane solution (e) had a solid content concentration of 41% by weight and the polysiloxane had a weight average molecular weight of 14900. In addition, the content ratio of the organosilane represented by the general formula (1) in the polysiloxane was 40% in terms of the mole ratio of Si atoms, and the content ratio of the organosilane represented by the general formula (2) in the polysiloxane was 60% in terms of the mole ratio of Si atoms.

### Synthesis Example 6 Synthesis of Polysiloxane Solution (f)

Into a 500 mL three-necked flask, 20.43 g (0.15 mol) of methyltrimethoxysilane, 99.15 g (0.50 mol) of phenyltrimethoxysilane, 12.32 g (0.05 mol) of 2-(3,4-epoxycyclohexyl)ethyltrimethoxysilane, 45.67 g (0.30 mol, m=1) of tetramethoxysilane and 228.35 g of DAA were charged, and to the resulting mixture, an aqueous phosphoric acid solution having 1.067 g (0.6% by weight with respect to the weight of charged monomers) of phosphoric acid dissolved in 60.30 g of water was added over 10 minutes while stirring the mixture at room temperature. Thereafter, the flask was immersed in an oil bath of 40° C., the resulting mixture was stirred for 30 minutes, and then the oil bath was heated up to 115° C. over 30 minutes. The temperature of the solution reached 100° C. after a lapse of 1 hour from the start of heating and the solution was heated and stirred for further 4 hours (the temperature of the solution was 100 to 110° C. in the meantime) to obtain a polysiloxane solution (f). In addition, a nitrogen gas was flowed at a flow rate of 0.05 l (liter)/min during the heating and stirring. During the reaction, 129 g in total of methanol and water as by-products were distilled out.

The obtained polysiloxane solution (f) had a solid content concentration of 39% by weight and the polysiloxane had a weight average molecular weight of 9000. In addition, the content ratio of the organosilane represented by the general formula (1) in the polysiloxane was 50% in terms of the mole ratio of Si atoms, and the content ratio of the organosilane represented by the general formula (2) in the polysiloxane was 30% in terms of the mole ratio of Si atoms.

### Synthesis Example 7 Synthesis of Polysiloxane Solution (g)

Into a 500 mL three-necked flask, 40.86 g (0.30 mol) of methyltrimethoxysilane, 69.41 g (0.35 mol) of phenyltrimethoxysilane, 12.32 g (0.05 mol) of 2-(3,4-epoxycyclohexyl)ethyltrimethoxysilane, 35.25 g (0.30 mol) of M Silicate 51 ((m=4, average) produced by TAMA CHEMICALS CO., LTD.), 140.37 g of PGMEA and 15.60 g of methanol were charged, and to the resulting mixture, an aqueous phosphoric acid solution having 0.63 g (0.4% by weight with respect to the weight of charged monomers) of phosphoric acid dissolved in 52.20 g of water was added over 10 minutes while stirring the mixture at room temperature. Thereafter, the flask was immersed in an oil bath of 40° C., the resulting mixture was stirred for 30 minutes, and then the oil bath was heated up to 115° C. over 30 minutes. The temperature of the solution reached 100° C. after a lapse of 1 hour from the start of heating and the solution was heated and stirred for further 2 hours (the temperature of the solution was 100 to 110° C. in the meantime) to obtain a polysiloxane solution (g). In addition, a nitrogen gas was flowed at a flow rate of 0.05 l (liter)/min during the heating and stirring. During the reaction, 141 g in total of methanol and water as by-products were distilled out.

The obtained polysiloxane solution (g) had a solid content concentration of 42% by weight and the polysiloxane had a weight average molecular weight of 12300. In addition, the content ratio of the organosilane represented by the general formula (1) in the polysiloxane was 35% in terms of the mole ratio of Si atoms, and the content ratio of the organosilane represented by the general formula (2) in the polysiloxane was 30% in terms of the mole ratio of Si atoms.

### Synthesis Example 8 Synthesis of Polysiloxane Solution (h)

Into a 500 mL three-necked flask, 44.95 g (0.33 mol) of methyltrimethoxysilane, 54.53 g (0.25 mol) of phenyltrimethoxysilane, 13.55 g (0.055 mol) of 2-(3,4-epoxycyclohexyl)ethyltrimethoxysilane, 25.85 g (0.22 mol) of M Silicate 51 ((m=4, average) produced by TAMA CHEMICALS CO., LTD.), 51.55 g (0.22 mol) of 3-acryloxypropyltrimethoxysilane, 173.23 g of PGMEA and 19.25 g of ethanol were charged, and to the resulting mixture, an aqueous phosphoric acid solution having 0.95 g (0.5% by weight with respect to the weight of charged monomers) of phosphoric acid dissolved in 58.41 g of water was added over 10 minutes while stirring the mixture at room temperature. Thereafter, the flask was immersed in an oil bath of 40° C., the resulting mixture was stirred for 30 minutes, and then the oil bath was heated up to 115° C. over 30 minutes. The temperature of the solution reached 100° C. after a lapse of 1 hour from the start of heating and the solution was heated and stirred for further 2 hours (the temperature of the solution was adjusted to 95 to 105° C.) to obtain a polysiloxane solution (h). In addition, a nitrogen gas was flowed at a flow rate of 0.05 l (liter)/min during the heating and stirring. During the reaction, 156 g in total of methanol and water as by-products were distilled out.

The obtained polysiloxane solution (h) had a solid content concentration of 42% by weight and the polysiloxane had a weight average molecular weight of 9100. In addition, the content ratio of the organosilane represented by the general formula (1) in the polysiloxane was 25% in terms of the mole ratio of Si atoms, and the content ratio of the organosilane represented by the general formula (2) in the polysiloxane was 20% in terms of the mole ratio of Si atoms.

### Synthesis Example 9 Synthesis of Polysiloxane Solution (i)

Into a 500 mL three-necked flask, 118.98 g (0.60 mol) of phenyltrimethoxysilane, 59.61 g (0.4 mol) of M Silicate 51 ((m=4, average) produced by TAMA CHEMICALS CO., LTD.) and 197.57 g of DAA were charged, and to the resulting mixture, an aqueous phosphoric acid solution having 1.07 g (0.6% by weight with respect to the weight of charged monomers) of phosphoric acid dissolved in 50.40 g of water was added over 10 minutes while stirring the mixture at room temperature. Thereafter, the flask was immersed in an oil bath of 40° C., the resulting mixture was stirred for 30 minutes, and then the oil bath was heated up to 115° C. over 30 minutes. The temperature of the solution reached 100° C. after a lapse of 1 hour from the start of heating and the solution was heated and stirred for further 4 hours (the temperature of the solution was 100 to 110° C. in the meantime) to obtain a polysiloxane solution (i). In addition, a nitrogen gas was flowed at a flow rate of 0.05 l (liter)/min during the heating and stirring. During the reaction, 131 g in total of methanol and water as by-products were distilled out.

The obtained polysiloxane solution (i) had a solid content concentration of 37% by weight and the polysiloxane had a weight average molecular weight of 10100. In addition, the content ratio of the organosilane represented by the general formula (1) in the polysiloxane was 60% in terms of the mole ratio of Si atoms, and the content ratio of the organosilane represented by the general formula (2) in the polysiloxane was 40% in terms of the mole ratio of Si atoms. Synthesis Example 10 Synthesis of Polysiloxane Solution (j)

Into a 500 mL three-necked flask, 47.67 g (0.35 mol) of methyltrimethoxysilane, 99.15 g (0.5 mol) of phenyltrimethoxysilane, 12.32 g (0.05 mol) of 2-(3,4-epoxycyclohexyl)ethyltrimethoxysilane, 11.75 g (0.10 mol) of M Silicate 51 ((m=4, average) produced by TAMA CHEMICALS CO., LTD.) and 170.77 g of PGMEA were charged, and to the resulting mixture, an aqueous phosphoric acid solution having 0.53 g (0.3% by weight with respect to the weight of charged monomers) of phosphoric acid dissolved in 54.00 g of water was added over 10 minutes while stirring the mixture at room temperature. Thereafter, the flask was immersed in an oil bath of 40° C., the resulting mixture was stirred for 30 minutes, and then the oil bath was heated up to 115° C. over 30 minutes. The temperature of the solution reached 100° C. after a lapse of 1 hour from the start of heating and the solution was heated and stirred for further 2 hours (the temperature of the solution was 100 to 110° C. in the meantime) to obtain a polysiloxane solution (j). In addition, a nitrogen gas was flowed at a flow rate of 0.05 l (liter)/min during the heating and stirring. During the reaction, 123 g in total of methanol and water as by-products were distilled out.

The obtained polysiloxane solution (j) had a solid content concentration of 43% by weight and the polysiloxane had a weight average molecular weight of 8500. In addition, the content ratio of the organosilane represented by the general formula (1) in the polysiloxane was 50% in terms of the mole ratio of Si atoms, and the content ratio of the organosilane represented by the general formula (2) in the polysiloxane was 10% in terms of the mole ratio of Si atoms.

### Synthesis Example 11 Synthesis of Polysiloxane Solution (k)

Into a 500 mL three-necked flask, 47.67 g (0.35 mol) of methyltrimethoxysilane, 99.15 g (0.50 mol) of phenyltrimethoxysilane, 12.32 g (0.05 mol) of 2-(3,4-epoxycyclohexyl)ethyltrimethoxysilane, 15.22 g (0.10 mol, m=1) of tetramethoxysilane and 170.77 g of PGMEA were charged, and to the resulting mixture, an aqueous phosphoric acid solution having 0.52 g (0.3% by weight with respect to the weight of charged monomers) of phosphoric acid dissolved in 56.70 g of water was added over 10 minutes while stirring the mixture at room temperature. Thereafter, the flask was immersed in an oil bath of 40° C., the resulting mixture was stirred for 30 minutes, and then the oil bath was heated up to 115° C. over 30 minutes. The temperature of the solution reached 100° C. after a lapse of 1 hour from the start of heating and the solution was heated and stirred for further 2 hours (the temperature of the solution was 100 to 110° C. in the meantime) to obtain a polysiloxane solution (k). In addition, a nitrogen gas was flowed at a flow rate of 0.05 l (liter)/min during the heating and stirring. During the reaction, 129 g in total of methanol and water as by-products were distilled out.

The obtained polysiloxane solution (k) had a solid content concentration of 43% by weight and the polysiloxane had a weight average molecular weight of 8500. In addition, the content ratio of the organosilane represented by the general formula (1) in the polysiloxane was 50% in terms of the mole ratio of Si atoms, and the content ratio of the organosilane represented by the general formula (2) in the polysiloxane was 10% in terms of the mole ratio of Si atoms.

### Synthesis Example 12 Synthesis of Polysiloxane Solution (l)

Into a 500 mL three-necked flask, 54.48 g (0.40 mol) of methyltrimethoxysilane, 99.15 g (0.50 mol) of phenyltrimethoxysilane, 24.64 g (0.1 mol) of 2-(3,4-epoxycyclohexyl)ethyltrimethoxysilane and 179.50 g of DAA were charged, and to the resulting mixture, an aqueous phosphoric acid solution having 0.54 g (0.3% by weight with respect to the weight of charged monomers) of phosphoric acid dissolved in 55.8 g of water was added over 10 minutes while stirring the mixture at room temperature. Thereafter, the flask was immersed in an oil bath of 40° C., the resulting mixture was stirred for 30 minutes, and then the oil bath was heated up to 115° C. over 30 minutes. The temperature of the solution reached 100° C. after a lapse of 1 hour from the start of heating and the solution was heated and stirred for further 2 hours (the temperature of the solution was 100 to 110° C. in the meantime) to obtain a polysiloxane solution (1). In addition, a nitrogen gas was flowed at a flow rate of 0.05 l (liter)/min during the heating and stirring. During the reaction, 121 g in total of methanol and water as by-products were distilled out.

The obtained polysiloxane solution (1) had a solid content concentration of 43% by weight and the polysiloxane had a weight average molecular weight of 3200. In addition, the content ratio of the organosilane represented by the general formula (1) in the polysiloxane was 50% in terms of the mole ratio of Si atoms, and the content ratio of the organosilane represented by the general formula (2) in the polysiloxane was 0% in terms of the mole ratio of Si atoms.

### Synthesis Example 13 Synthesis of Polysiloxane Solution (m)

Into a 500 mL three-necked flask, 54.48 g (0.40 mol) of methyltrimethoxysilane, 29.75 g (0.15 mol) of phenyltrimethoxysilane, 12.32 g (0.05 mol) of 2-(3,4-epoxycyclohexyl)ethyltrimethoxysilane, 23.50 g (0.20 mol) of M Silicate 51 ((m=4, average) produced by TAMA CHEMICALS CO., LTD.), 46.86 g (0.20 mol) of 3-acryloxypropyltrimethoxysilane and 196.26 g of DAA were charged, and to the resulting mixture, an aqueous phosphoric acid solution having 0.33 g (0.2% by weight with respect to the weight of charged monomers) of phosphoric acid dissolved in 53.10 g of water was added over 10 minutes while stirring the mixture at room temperature. Thereafter, the flask was immersed in an oil bath of 40° C., the resulting mixture was stirred for 30 minutes, and then the oil bath was heated up to 115° C. over 30 minutes. The temperature of the solution reached 100° C. after a lapse of 1 hour from the start of heating and the solution was heated and stirred for further 2 hours (the temperature of the solution was 95 to 105° C. in the meantime) to obtain a polysiloxane solution (m). In addition, a nitrogen gas was flowed at a flow rate of 0.05 l (liter)/min during the heating and stirring. During the reaction, 120 g in total of methanol and water as by-products were distilled out.

The obtained polysiloxane solution (m) had a solid content concentration of 43% by weight and the polysiloxane had a weight average molecular weight of 9500. In addition, the content ratio of the organosilane represented by the general formula (1) in the polysiloxane was 15% in terms of the mole ratio of Si atoms, and the content ratio of the organosilane represented by the general formula (2) in the polysiloxane was 20% in terms of the mole ratio of Si atoms.

### Synthesis Example 14 Synthesis of Acrylic Resin Solution (a)

Into a 500 ml flask, 5 g of 2,2′-azobis (isobutyronitrile), 5 g of tert-dodecanethiol and 180 g of PGMEA were charged. Thereafter, 30 g of methacrylic acid, 35 g of benzylmethacrylate and 35 g of tricyclo[5.2.1.0^{2.6}]decan-8-yl methacrylate were charged, the resulting mixture was stirred at room temperature and the inside of the flask was replaced with nitrogen, and then the mixture was heated and stirred at 70° C. for 5 hours. Then, to the resulting solution, 15 g of glycidyl methacrylate, 1 g of dimethylbenzylamine and 0.2 g of p-methoxyphenol were added, and the resulting mixture was heated and stirred at 90° C. for 4 hours to obtain an acrylic resin solution (a).

The obtained acrylic resin solution (a) had a solid content concentration of 40% by weight, and the acrylic resin had a weight average molecular weight of 12000 and an acid value of 91 mg KOH/g.

### Synthesis Example 15 Synthesis of Quinone Diazide Compound (a)

In a dry nitrogen stream, 21.23 g (0.05 mol) of TrisP-PA (trade name, produced by Honshu Chemical Industry Co., Ltd.) and 37.62 g (0.14 mol) of 5-naphthoquinonediazidesulfonylic acid chloride were dissolved in 450 g of 1,4-dioxane, and the solution was kept at room temperature. To the solution, 15.58 g (0.154 mol) of triethylamine mixed with 50 g of 1,4-dioxane was added dropwise while keeping an internal temperature of a system at lower than 35° C. After the completion of dropwise addition, the resulting mixture was stirred at 30° C. for 2 hours. Triethylamine salt was separated by filtration and filtrate was charged into water. Thereafter, the formed precipitate was collected by filtration. This precipitate was dried with a vacuum drier to obtain a quinone diazide compound (a) having the following structure.

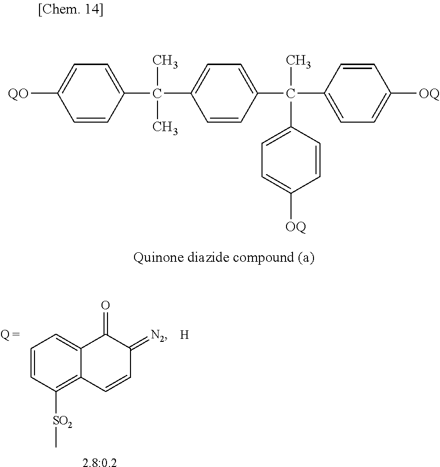

### Synthesis Example 16 Synthesis of Quinone Diazide Compound (b)

In a dry nitrogen stream, 15.32 g (0.05 mol) of TrisP-HPA (trade name, produced by Honshu Chemical Industry Co., Ltd.) and 26.87 g (0.1 mol) of 5-naphthoquinonediazidesulfonylic acid chloride were dissolved in 450 g of 1,4-dioxane, and the solution was kept at room temperature. To the solution, 11.13 g (0.11 mol) of triethylamine mixed with 50 g of 1,4-dioxane was added dropwise while keeping an internal temperature of a system at lower than 35° C. After the completion of dropwise addition, the resulting mixture was stirred at 30° C. for 2 hours. Triethylamine salt was separated by filtration and filtrate was charged into water. Thereafter, the formed precipitate was collected by filtration. This precipitate was dried with a vacuum drier to obtain a quinone diazide compound (b) having the following structure.

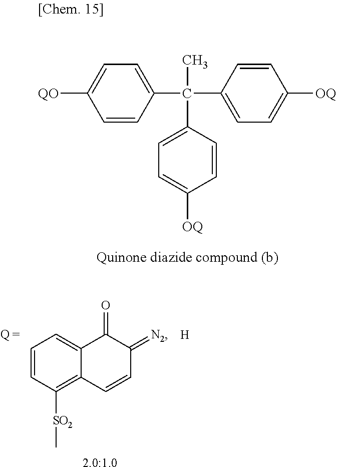

### Synthesis Example 17 Synthesis of Quinone Diazide Compound (c)

In a dry nitrogen stream, 15.32 g (0.05 mol) of Ph-cc-AP-MF (trade name, produced by Honshu Chemical Industry Co., Ltd.) and 37.62 g (0.14 mol) of 5-naphthoquinonediazidesulfonylic acid chloride were dissolved in 450 g of 1,4-dioxane, and the solution was kept at room temperature. To the solution, 15.58 g (0.154 mol) of triethylamine mixed with 50 g of 1,4-dioxane was added dropwise while keeping an internal temperature of a system at lower than 35° C. After the completion of dropwise addition, the resulting mixture was stirred at 30° C. for 2 hours. Triethylamine salt was separated by filtration and filtrate was charged into water. Thereafter, the formed precipitate was collected by filtration. This precipitate was dried with a vacuum drier to obtain a quinone diazide compound (c) having the following structure.

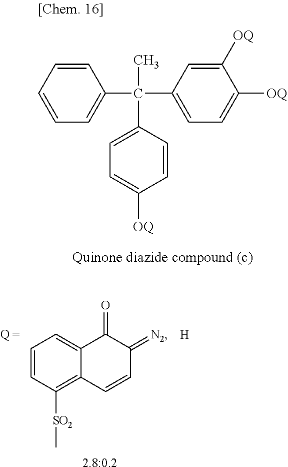

### Synthesis Example 18 Synthesis of Quinone Diazide Compound (d)

A quinone diazide compound (d) having the following structure was prepared in the same manner as in Synthesis Example 10 except for changing an additive amount of the 5-naphthoquinonediazidesulfonylic acid chloride to 33.59 g (0.125 mol).

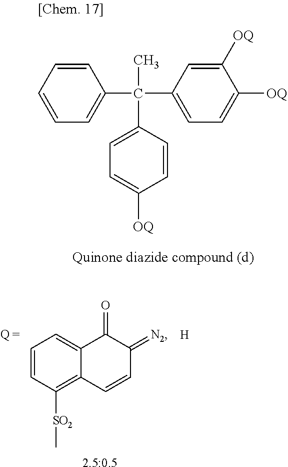

### Example 1

21.88 g of the polysiloxane solution (a) obtained in Synthesis Example 1, 0.98 g of the quinone diazide compound (a) obtained in Synthesis Example 9, 2.92 g of DAA as a solvent and 3.96 g of GEL were mixed and stirred under a yellow lamp to form a uniform solution, and then filtrated with a filter with a pore size of 0.45 μm to prepare a composition 1.

The composition 1 was applied onto a silicon wafer and an OA-10 glass sheet (manufactured by Nippon Electric Glass Co., Ltd.) at an arbitrary rotating speed with a spin coater (1H-360S manufactured by MIKASA CO., LTD.), and it was pre-baked at 100° C. for 2 minutes with a hot plate (SCW-636 manufactured by Dainippon Screen Mfg. Co., Ltd.) to form a pre-baked film having a film thickness of 3 μm. The prepared film was exposed to an ultra high pressure mercury lamp through a gray scale mask for sensitivity measurement with a parallel light mask aligner (hereinafter, abbreviated to a PLA) (PLA-501F manufactured by Canon Inc.) to form a pattern. The exposed film was developed by showering of ELM-D (trade name, produced by MITSUBISHI GAS CHEMICAL CO., INC.), which is a 2.38% by weight aqueous solution of tetramethylammonium hydroxide, for 60 seconds using an automatic developing apparatus (AD-2000 manufactured by Takizawa Sangyo Co., Ltd.), and then rinsed with water for 30 seconds. Thereafter, as bleaching exposure, the entire surface of the film was exposed to an ultra high pressure mercury lamp at 3000 J/m² (on the exposure amount at wavelength 365 nm equivalent basis) with a PLA (PLA-501F manufactured by Canon Inc.). Thereafter, the film was soft-baked at 110° C. for 2 minutes with a hot plate, and then was cured at 230° C. for 1 hour in the air with an oven (IHPS-222 manufactured by Tabai Espec Corp.) to prepare a cured film.

The results of evaluations of photosensitive properties and cured film properties are shown in Table 2. The evaluations in the table were performed according to the following methods. The following evaluations (4) to (8) were performed by using a silicon wafer substrate and evaluations (9) to (11) were performed by using an OA-10 glass sheet.

(4) Measurement of Film Thickness

Ramda-Ace STM-602 (trade name, manufactured by Dainippon Screen Mfg. Co., Ltd.) was used to measure the thickness of a pre-baked film at a refractive index of 1.50.

(5) Calculation of Normalized Remaining Film Thickness

The normalized remaining film thickness was determined according to the following formula.

Normalized remaining film thickness (%)=(film thickness of unexposed area after development)/(film thickness after prebake)×100

(6) Determination of Sensitivity

After exposure and development, the exposure amount at which a 10 μm line and space pattern is formed at a width ratio of 1:1 (hereinafter, the exposure amount is referred to as an optimum exposure amount) was taken as the sensitivity.

(7) Determination of Resolution

The minimum pattern size at the optimum exposure amount after development was referred to as a resolution after development and the minimum pattern size at the optimum exposure amount after curing was referred to as a resolution after curing.

(8) Heat Resistance

A cured film prepared by the method described in Example 1 was scraped off the substrate and about 10 mg of the scraped film piece was put in an aluminum cell. By use of a thermogravimetric apparatus (TGA-50, manufactured by Shimadzu Corporation), the film piece was heated at a heating rate of 10° C./min up to 150° C. in a nitrogen atmosphere, maintained at 150° C. for 1 hour, and then heated at a heating rate of 10° C./min up to 400° C. At this time, a temperature Td1% at which the ratio of weight loss was 1% was measured and compared. A higher Td1% indicates that heat resistance is good.

(9) Measurement of Light Transmittance

First, the ultraviolet and visible absorption spectrum of the OA-10 glass sheet alone was measured as a reference with Multi Spec-1500 (trade name, manufactured by Shimadzu Corporation). Next, a cured film of the composition was formed on the OA-10 glass sheet (pattern exposure was not performed), and this sample was measured with a single beam to determine a light transmittance per 3 μm thickness at a wavelength of 400 nm, and the difference between the light transmittance and the reference was taken as the light transmittance of the cured film.

(10) Chemical Resistance Test

The cured film used in the measurement of light transmittance was heat-treated at 300° C. for 250 seconds, and lines spaced 1 mm apart were inscribed on the cured film with a cutter to prepare 10×10 squares. Thereafter, the cured film was immersed in an ITO etching liquid (hydrochloric acid/potassium chloride/water=5/7/98 (weight ratio)) at 50° C. for 300 seconds, and thereafter a cellophane adhesive tape was adhered to the squares, and a state of the squares remaining at the time of peeling this tape off was observed. The ratio of the squares remaining without being peeled was evaluated according to the following criteria. x: 100% of the squares were peeled, Δx: ratio of the remaining squares was less than 40%, ΔΔ: ratio of the remaining squares was not less than 40% and less than 60%, Δ: ratio of the remaining squares was not less than 60% and less than 80%, O: ratio of the remaining squares was not less than 80% and less than 95%, ⊙: ratio of the remaining squares was not less than 95%.

(11) Measurement of Light Transmittance After High Temperature Heat Treatment

First, the ultraviolet and visible absorption spectrum of the OA-10 glass sheet alone was measured as a reference with Multi Spec-1500 (trade name, manufactured by Shimadzu Corporation). Next, a cured film of the composition was formed on the OA-10 glass sheet (pattern exposure was not performed), the cured film was heat-treated at 330° C. for 300 seconds, and the resulting sample was measured with a single beam to determine a light transmittance per 3 μm thickness at a wavelength of 400 nm, and the difference between the light transmittance and the reference was taken as the light transmittance of the cured film.

### Examples 2 to 13

### Comparative Examples 1 to 3

Compositions 2 to 16 were prepared so as to have the compositions shown in Table 1 as with the composition 1. In addition, KBM-303 used as a silane coupling agent was 2-(3,4-epoxycyclohexyl)ethyltrimethoxysilane produced by Shin-Etsu Chemical Co., Ltd. and KBM-403 was 3-glycidoxypropyltrimethoxysilane produced by Shin-Etsu Chemical Co., Ltd. “NIKALAC” MX-270 (trade name, manufactured by SANWA CHEMICAL CO., LTD.) used as a crosslinking agent is a compound having the following structure. Further, CGI-MDT (trade name, produced by Ciba Specialty Chemicals Inc.) and WPAG-469 (trade name, produced by Wako Pure Chemical Industries, Ltd.), which were used as a crosslinking promoter, were a 20% PGMEA solution of 4-methylphenyldiphenylsulfonium perfluorobutanesulfonate, and DPA (trade name, produced by Kawasaki Kasei Chemicals Ltd.) used as a sensitizer was 9,10-dipropoxyanthracene.

(12) Preparation Method of Touch Panel Device

A preparation method of a touch panel device will be described with reference to an example. A thin film of a metal oxide commonly used, such as indium tin oxide (ITO) or tin antimonate, or a metal such as gold, silver, copper, or aluminum was used for the transparent electrode. These transparent electrodes are formed by a method hitherto used, for example, a physical method such as vacuum deposition, sputtering, ion plating or ion beam deposition, or a chemical vapor-phase deposition method.

ITO was deposited by vapor deposition on a glass substrate having a thickness of about 1 mm, a resist material was patterned thereon by a photolithography technique and chemically etched by the above-mentioned ITO etching liquid, and a rhombus pattern was formed by peeling the resist material to prepare a glass substrate having a transparent electrode of 200 Å in thickness.

The composition 1 was applied onto a site where the transparent electrode intersects with a transparent electrode to be formed later by spin coating, and it was pre-baked at 100° C. for 2 minutes with a hot plate (SCW-636 manufactured by Dainippon Screen Mfg. Co., Ltd.) to form a pre-baked film having a film thickness of 3 μm. The prepared film was exposed to an ultra high pressure mercury lamp through a mask with the PLA (PLA-501F manufactured by Canon Inc.) to form a pattern. The exposed film was developed by showering of ELM-D (trade name, produced by MITSUBISHI GAS CHEMICAL CO., INC.), which is a 2.38% by weight aqueous solution of tetramethylammonium hydroxide, for 60 seconds by using an automatic developing apparatus (AD-2000 manufactured by Takizawa Sangyo Co., Ltd.), and then rinsed with water for 30 seconds. Thereafter, as bleaching exposure, the entire surface of the film was exposed to an ultra high pressure mercury lamp at 3000 J/m² (on the exposure amount at wavelength 365 nm equivalent basis) with the PLA. Thereafter, the film was soft-baked at 110° C. for 2 minutes with a hot plate, and then was cured at 230° C. for 1 hour in the air with an oven (IHPS-222 manufactured by Tabai Espec Corp.) to prepare an insulation film.

ITO was deposited by vapor deposition on the insulation film as with the case described above and the ITO film was patterned to prepare a transparent electrode. The composition 1 was applied onto the entire surface of the ITO as a transparent protective film to prepare a touch panel device. Ends of a group of electrodes composing each transparent electrode were respectively connected to a resistance.

Examples of a material of the transparent protective film, in addition to polysiloxane, include thermoplastic resins such as an acrylic resin, polyvinyl chloride, polyester, polyamide, polycarbonate, and a fluorine-containing resin; thermosetting resins such as polyurethane, an epoxy resin, and polyimide; photopolymerizable resins such as ultraviolet-curable acrylic resin, ultraviolet-curable epoxy resin, ultraviolet-curable urethane resin, ultraviolet-curable polyester resin and ultraviolet-curable silicone resin; and silicon-based CVD inorganic materials, and are not particularly limited. From the viewpoint of transparency and visibility of a touch panel, it is preferred to employ a combination of these materials, in which the difference in a refractive index between the insulating material and the transparent protective film is 0.02 or less and more preferably 0.01 or less.

TABLE 1

| | | [symbol] | [symbol] | | |
|---|---|---|---|---|---|
| | | compound | compound | | |
| | | represented | represented | | |
| | Polysiloxane | by formula | by formula | | Naphthoquinone |
| | solution | [symbol] | [symbol] | Solvent | diazide compound |
| Composition | polysiloxane | 50% | 15% | DAA: 10.13 g | naphthoquinone |
| 1 | solution (a) | | | PGMEA: 3.48 g | diazide compound |
| | 15.21 g | | | | (a) 0.47 g |
| Composition | polysiloxane | 50% | 30% | PGMEA: 7.25 g | naphthoquinone |
| 2 | solution (b) | | | EDM: 4.56 | diazide compound |
| | 15.01 g | | | DPM: 2.28 g | (b) 0.59 g |
| Composition | polysiloxane | 50% | 40% | PGMEA: 6.46 g | naphthoquinone |
| 3 | solution (c) | | | EDM: 4.56 g | diazide compound |
| | 15.72 g | | | DPM: 2.28 g | (c) 0.59 g |
| Composition | polysiloxane | 50% | 50% | DAA: 3.42 g | naphthoquinone |
| 4 | solution (d) | | | PGMEA: 8.86 g | diazide compound |
| | 16.93 g | | | | (c) 0.59 g |
| Composition | polysiloxane | 40% | 60% | DAA: 4.23 g | naphthoquinone |
| 5 | solution (e) | | | PGMEA: 8.86 g | diazide compound |
| | 16.93 g | | | | (c) 0.59 g |
| Composition | polysiloxane | 50% | 30% | DAA: 5.70 g | naphthoquinone |
| 6 | solution (f) | | | PGMEA: 6.59 g | diazide compound |
| | 16.93 g | | | | (c) 0.59 g |
| Composition | polysiloxane | 35% | 30% | DAA: 11.27 g | naphthoquinone |
| 7 | solution (g) | | | PGMEA: 1.90 g | diazide compound |
| | 15.72 g | | | | (c) 0.59 g |
| Composition | polysiloxane | 25% | 20% | DAA: 11.27 g | naphthoquinone |
| 8 | solution (h) | | | PGMEA: 1.90 g | diazide compound |
| | 15.72 g | | | | (c) 0.59 g |
| Composition | polysiloxane | 60% | 40% | DAA: 2.51 g | naphthoquinone |
| 9 | solution (i) | | | PGMEA: 8.88 g | diazide compound |
| | 17.84 g | | | | (c) 0.59 g |
| Composition | polysiloxane | 50% | 30% | DAA: 5.90 g | naphthoquinone |
| 10 | solution (b) | | | PGMEA: 6.56 g | diazide compound |
| | 14.04 g | | | GBL: 8.80 g | (d) 0.80 g |
| Composition | polysiloxane | 50%. | 30% | DAA: 7.92 g | naphthoquinone |
| 11 | solution (b) | | | PGMEA: 0.79 g | diazide compound |
| | 13.63 g | | | | (d) 0.95 g |
| Composition | polysiloxane | 50% | 10% | DAA: 10.13 g | naphthoquinone |
| 12 | solution (j) | | | PGMEA: 3.48 g | diazide compound |
| | 15.21 g | | | | (a) 0.47 g |
| Composition | polysiloxane | 50% | 10% | DAA: 10.13 g | naphthoquinone |
| 13 | solution (k) | | | PGMEA: 3.48 g | diazide compound |
| | 15.21 g | | | | (a) 0.47 g |
| Composition | polysiloxane | 50% | 0% | DAA: 4.97 g | naphthoquinone |
| 14 | solution (1) | | | PGMEA: 8.85 g | diazide compound |
| | 15.35 g | | | | (c) 0.59 g |
| Composition | — | | | DAA: 5.94 g | naphthoquinone |
| 15 | | | | PGMEA: 0.71 g | diazide compound |
| | | | | | (b) 0.96 g |
| Composition | polysiloxane | 15% | 20% | DAA: 4.97 g | naphthoquinone |
| 16 | solution (m) | | | PGMEA: 8.85 g | diazide compound |
| | 15.35 g | | | | (c) 0.59 g |

| | Silane | | Cross- | Cross- | |
|---|---|---|---|---|---|
| | coupling | Acrylic resin | linking | linking | Sensi- |
| | agent | solution | agent | promoter | tizer |
| Composition | — | — | — | — | — |
| 1 | | | | | |
| Composition | | — | — | — | — |
| 2 | | | | | |
| Composition | | — | — | — | — |
| 3 | | | | | |
| Composition | | — | — | — | — |
| 4 | | | | | |
| Composition | | — | — | — | — |
| 5 | | | | | |
| Composition | | — | — | — | — |
| 6 | | | | | |
| Composition | | — | — | — | — |
| 7 | | | | | |
| Composition | | — | — | — | — |
| 8 | | | | | |
| Composition | | — | — | — | — |
| 9 | | | | | |
| Composition | KBM303: | — | — | CGI-MDT: | DPA: |
| 10 | 0.18 g | | | 0.06 g | 0-03 g |
| Composition | KBM403: | — | NIKALAC | — | — |
| 11 | 0.18 g | | MX-270: | | |
| | | | 0.06 g | | |
| Composition | | | | | |
| 12 | | | | | |
| Composition | | | | | |
| 13 | | | | | |
| Composition | — | — | — | — | — |
| 14 | | | | | |
| Composition | KBM303: | acrylic resin | NIKALAC | WPAG- | DPA: |
| 15 | 0.18 g | solution (a) | MX-270: | 469: | 0.04 g |
| | | 21.91 g | 0.18 g | 0.09 g | |
| | | (Mw = | | | |
| | | 12000) | | | |
| Composition | | — | — | — | — |
| 16 | | | | | |

[symbol]

indicates data missing or illegible when filed

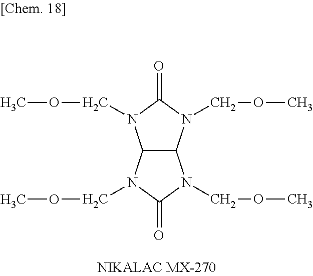

The obtained compositions were evaluated in the same manner as in Example 1. However, in the evaluation of Comparative Example 2, development was performed by showering for 60 seconds with a 0.4% by weight aqueous solution of tetramethylammonium hydroxide.

The results of evaluations are shown in Table 2.

TABLE 2

| | | Photosensitive properties | | | |
|---|---|---|---|---|---|
| | | Film | Normalized | | |
| | | thickness | remaining | | Resolution |
| | | after | film | | after |
| | | prebaking | thickness | Sensitivity | development |
| | Composition | (μm) | (%) | (J/m2) | (μm) |
| Example 1 | Composition | 3.0 | 94 | 360 | 4 |
| | 1 | | | | |
| Example 2 | Composition | 3.0 | 95 | 320 | 3 |
| | 2 | | | | |
| Example 3 | Composition | 3.0 | 96 | 320 | 2 |
| | 3 | | | | |
| Example 4 | Composition | 3.0 | 96 | 280 | 2 |
| | 4 | | | | |
| Example 5 | Composition | 3.0 | 97 | 280 | 2 |
| | 5 | | | | |
| Example 6 | Composition | 3.0 | 95 | 360 | 3 |
| | 6 | | | | |
| Example 7 | Composition | 3.0 | 95 | 320 | 3 |
| | 7 | | | | |
| Example 8 | Composition | 3.0 | 94 | 320 | 3 |
| | 8 | | | | |
| Example 9 | Composition | 3.0 | 95 | 280 | 2 |
| | 9 | | | | |
| Example 10 | Composition | 3.0 | 93 | 480 | 1 |
| | 10 | | | | |
| Example 11 | Composition | 3.0 | 92 | 500 | 2 |
| | 11 | | | | |
| Example 12 | Composition | 3.0 | 93 | 400 | 5 |
| | 12 | | | | |
| Example 13 | Composition | 3.0 | 92 | 440 | 5 |
| | 13 | | | | |
| Comparative | Composition | 3.0 | 95 | 440 | 6 |
| Example 1 | 14 | | | | |
| Comparative | Composition | 3.0 | 91 | 440 | 6 |
| Example 2 | 15 | | | | |
| Comparative | Composition | 3.0 | 92 | 440 | 6 |
| Example 3 | 16 | | | | |

| | Properties of cured film | | | | | |
|---|---|---|---|---|---|---|
| | Film | | | | Light | |
| | thickness | Resolution | | Light | transmittance | |
| | after | after | | transmittance | after heat | |
| | curing | curing | Td1% | of cured film | treatment at | Chemical |
| | (μm) | (μm) | (° C.) | (%) | 330° C. (%) | resistance |
| Example 1 | 2.7 | 4 | 362 | 99 | 96 | Δ |
| Example 2 | 2.7 | 3 | 350 | 98 | 96 | ⊚ |
| Example 3 | 2.7 | 2 | 358 | 98 | 97 | ⊚ |
| Example 4 | 2.7 | 2 | 358 | 98 | 97 | ⊚ |
| Example 5 | 2.7 | 2 | 360 | 98 | 97 | ⊚ |
| Example 6 | 2.7 | 3 | 355 | 98 | 96 | ⊚ |
| Example 7 | 2.7 | 3 | 355 | 98 | 96 | ⊚ |
| Example 8 | 2.6 | 3 | 318 | 98 | 96 | ◯ |
| Example 9 | 2.7 | 2 | 360 | 98 | 97 | ⊚ |
| Example 10 | 2.6 | 1 | 340 | 97 | 97 | ⊚ |
| Example 11 | 2.6 | 2 | 338 | 95 | 95 | ⊚ |
| Example 12 | 2.6 | 5 | 355 | 98 | 94 | Δ Δ |
| Example 13 | 2.6 | 6 | 350 | 97 | 94 | Δ X |
| Comparative | 2.7 | 20 | 345 | 98 | 91 | X |
| Example 1 | | | | | | |
| Comparative | 2.4 | 8 | 280 | 91 | 50 | Δ |
| Example 2 | | | | | | |
| Comparative | 2.6 | 8 | 352 | 91 | 89 | X |
| Example 3 | | | | | | |

### INDUSTRIAL APPLICABILITY

The photosensitive composition of the present invention is used for forming a planarization film for a thin film transistor (TFT) substrate of a liquid crystal display device, an organic EL display device or the like, a protective film or an insulation film for a touch panel sensor or the like, an interlayer insulation film of a semiconductor device, a planarization film or a microlens array pattern for a solid state image sensing device, or a core or clad material of a light waveguide of a photosemiconductor device or the like.

### EXPLANATION OF REFERENCE NUMERALS

1: glass substrate
2: transparent electrode (lower ITO)
3: transparent insulation film
4: transparent electrode (upper ITO)
5: transparent protective film

1. A positive photosensitive resin composition containing a polysiloxane, a naphthoquinone diazide compound, and a solvent,
wherein the polysiloxane contains an organosilane-derived structure represented by the general formula (1): 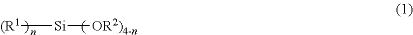
wherein R¹ represents an aryl group having 6 to 15 carbon atoms, plural R¹s may be the same or different, R² represents any of hydrogen, an alkyl group having 1 to 6 carbon atoms, an acyl group having 2 to 6 carbon atoms and an aryl group having 6 to 15 carbon atoms and plural R²s may be the same or different, and n represents an integer of 1 to 3, in an amount of 20% or more and 80% or less in terms of the ratio of the number of Si atom-moles to the number of Si atom-moles of the whole polysiloxane, and
wherein the polysiloxane contains an organosilane-derived structure represented by the general formula (2): 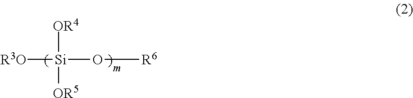
wherein R³ to R⁶ independently represent any of hydrogen, an alkyl group having 1 to 6 carbon atoms, an acyl group having 2 to 6 carbon atoms and an aryl group having 6 to 15 carbon atoms and m represents an integer of 1 to 11.

2. The positive photosensitive composition according to claim 1, wherein the polysiloxane further contains an organosilane-derived structure represented by the general formula (3): 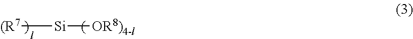
wherein R⁷ represents any of hydrogen, an alkyl group having 1 to 10 carbon atoms and an alkenyl group having 2 to 10 carbon atoms and plural R⁷s may be the same or different, R⁸ represents any of hydrogen, an alkyl group having 1 to 6 carbon atoms, an acyl group having 2 to 6 carbon atoms and an aryl group having 6 to 15 carbon atoms and plural R⁸s may be the same or different, and l represents an integer of 1 to 3.

3. The positive photosensitive composition according to claim 1, wherein the polysiloxane contains an organosilane-derived structure represented by the general formula (2) in an amount of 12% or more and 60% or less in terms of the ratio of the number of Si atom-moles to the number of Si atom-moles of the whole polysiloxane.

4. The positive photosensitive composition according to claim 1, wherein in the polysiloxane, R¹ in the general formula (1) is any group of a phenyl group, a tolyl group, a naphthyl group, an anthracenyl group, a phenanthrenyl group, a fluorenyl group, a fluorenonyl group, a pyrenyl group, an indenyl group and an acenaphthenyl group.

5. The positive photosensitive composition according to claim 1, wherein in the polysiloxane, m in the general formula (2) is an integer of 2 to 11.

6. The positive photosensitive composition according to claim 1, wherein the amount of the naphthoquinone diazide compound is 3 to 15 parts by weight with respect to 100 parts by weight of the polysiloxane.

7. The positive photosensitive composition according to claim 1, wherein the naphthoquinone diazide compound is a naphthoquinone diazide compound represented by the following general formula (4): 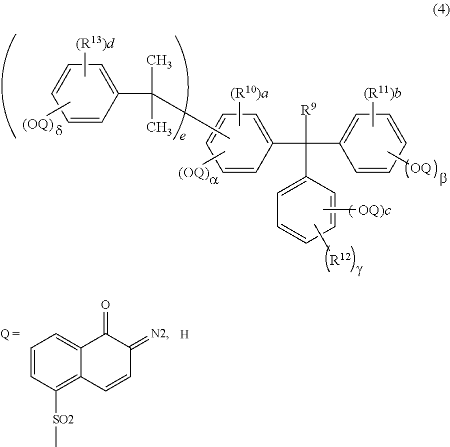
wherein R⁹ represents hydrogen or an alkyl group having 1 to 8 carbon atoms, R¹⁰, R¹¹, R¹² and R¹³ represent any of a hydrogen atom, an alkyl group having 1 to 8 carbon atoms, an alkoxyl group, a carboxyl group and an ester group, R¹⁰s, R¹¹s, R¹²s and R¹³s may be the same or different, Q represents either a 5-naphthoquinonediazidesulfonyl group or a hydrogen atom and not all the Qs are a hydrogen atom, and a, b, c, d, e, α, β and γ represent an integer of 0 to 4 and satisfy a relationship of α+β+γ+δ≧2.

8. A cured film formed from the positive photosensitive composition according to claim 1, wherein in the cured film, a transmittance per a film thickness of 3 μm at a wavelength of 400 nm is 90% or more.

9. A device comprising the cured film according to claim 1.

10. A device, wherein the device according to claim 9 is any one of a liquid crystal display device, an organic EL display device, a device for a touch panel sensor, a semiconductor device, a solid state image sensing device and a photosemiconductor device.
